(19) United States
(12) Patent Application Publication
(10) Pub. No.: US 2026/0126878 A1
(43) Pub. Date: May 7, 2026

(54) DISPLAY DEVICE

(71) Applicant: LG Display Co., Ltd., Seoul (KR)

(72) Inventors: NamYong GONG, Paju-si (KR); SungChul KIM, Paju-si (KR); HoonBae KIM, Paju-si (KR); SunYeop KIM, Paju-si (KR); Sung-Jin KANG, Paju-si (KR); Jongsung KIM, Paju-si (KR)

(73) Assignee: LG Display Co., Ltd., Seoul (KR)

(21) Appl. No.: 19/247,528

(22) Filed: Jun. 24, 2025

(30) Foreign Application Priority Data
Nov. 1, 2024 (KR) 10-2024-0153601

(51) Int. Cl. G06F 3/042; G06F 3/041; G09G 3/3233; H10H 29/37; H10H 29/80

(52) U.S. Cl. CPC G06F 3/0421; G06F 3/0412; G06F 3/0416; G09G 3/3233; H10H 29/37; H10H 29/8321; G09G 2300/0842; G09G 2300/0861; G09G 2354/00

(57) ABSTRACT

A display device can include a substrate, a plurality of light emitting devices disposed on the substrate and positioned in a display area, a plurality of column lines electrically connected to a first electrode of each of the plurality of light emitting devices, a plurality of row lines electrically connected to a second electrode of each of the plurality of light emitting devices, an optical driving device, and an optical detection device. The optical driving device can be positioned in the display area and overlaps with a first row line among the plurality of row lines. The optical driving device can emit a specific light of a first wavelength band according to a voltage difference between both ends of the optical driving device. The optical detection device can be disposed on the substrate and detects a specific light reflected from an outside of the display device and incident into the display device.

### CROSS-REFERENCE TO RELATED APPLICATION

This application claims priority to Korean Patent Application No. 10-2024-0153601, filed in the Republic of Korea on Nov. 1, 2024, which is hereby expressly incorporated by reference for all purposes as if fully set forth herein into the present application.

### BACKGROUND

### Field

Embodiments of the present disclosure relate to an apparatus and particularly to, for example, without limitation, a display device.

### Discussion of the Related Art

A display device is applied to various electronic devices such as televisions, mobile phones, laptops, and tablets. Display devices can include an organic light emitting display (OLED) including a self-luminous light emitting device, and a liquid crystal display (LCD) including a separate light source.

Recently, a display device with light emitting diodes (LED) is attracting attention as a next-generation display device. Since the light emitting diodes are made of inorganic materials rather than organic materials, a display device with the light emitting diode has a characteristics of a faster lighting speed, superior light emitting efficiency, and can display high-luminance images compared to a liquid crystal display or an organic light emitting display.

### SUMMARY OF THE DISCLOSURE

Embodiments of the present disclosure can provide a display device incorporating an optical touch sensor into the display panel of the display device.

Embodiments of the present disclosure can provide a display device including an optical driving device and an optical detection device having a structure corresponding to a light emitting device for a display as an optical touch sensor.

Embodiments of the present disclosure can provide a display device capable of reducing noise which can be caused by light emission for image display during optical touch sensing.

Embodiments of the present disclosure can provide a display device capable of embedding a driver for display driving and touch driving into the display panel, thereby reducing the number of driving components (e.g., drivers) connected to the outside of a display panel, reducing the number of assembly processes in the manufacturing process to enable the process optimization.

The objects of the embodiments of the present disclosure are not limited to the objects described in this disclosure, and other objects not mentioned will be clearly understood by those skilled in the art from the description below.

A display device according to embodiments of the present disclosure can include a substrate, a plurality of light emitting devices disposed on the substrate and positioned in a display area, a plurality of column lines electrically connected to a first electrode of each of the plurality of light emitting devices, a plurality of row lines electrically connected to a second electrode of each of the plurality of light emitting devices, an optical driving device disposed on the substrate and positioned in the display area, overlapping with a first row line among the plurality of row lines, and emitting a specific light of a first wavelength band according to a voltage difference between both ends of the optical driving device, and an optical detection device disposed on the substrate and detecting a specific light reflected from an outside and incident inside of the display device.

A display device according to embodiments of the present disclosure can include a substrate, a plurality of light emitting devices disposed on the substrate and positioned in a display area, a plurality of drivers configured to drive the plurality of light emitting devices, an optical driving device disposed on the substrate and positioned in the display area, emitting a specific light of a first wavelength band, and an optical detection device disposed on the substrate and positioned in the display area, detecting a specific light reflected from an outside and incident inside of the display device. The optical driving device can be driven by a first driver among the plurality of drivers, and the optical detection device can be driven by a second driver among the plurality of drivers.

According to embodiments of the present disclosure, it is possible to provide a display device incorporating an optical touch sensor into the display panel.

According to embodiments of the present disclosure, it is possible to provide a display device including an optical driving device and an optical detection device having a structure corresponding to a light emitting device for a display as an optical touch sensor. Accordingly, it is possible to implement easier design and production of a display panel and achieve the process optimization.

According to embodiments of the present disclosure, it is possible to provide a display device capable of reducing noise caused by light emission for image display during optical touch sensing.

According to embodiments of the present disclosure, it is possible to provide a display device capable of embedding a driver for display driving and touch driving into the display panel, thereby reducing the number of driving components (e.g., drivers) connected to the outside of a display panel, reducing the number of assembly processes in the manufacturing process to enable the process optimization.

The effects of the embodiments of the present disclosure are not limited to the effects mentioned above, and other effects not mentioned will be clearly understood by those skilled in the art from the description of the claims.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 illustrates a display device according to embodiments of the present disclosure.

FIG. 2 is a plan view of a display device according to embodiments of the present disclosure.

FIG. 3 is a plan view of a display panel according to embodiments of the present disclosure.

FIG. 4 is a plan view of a unit driving area of a display panel according to embodiments of the present disclosure.

FIG. 5 illustrates a sub-pixel of a display panel according to embodiments of the present disclosure.

FIG. 6 is a plan view of a display panel according to embodiments of the present disclosure.

FIG. 7 and FIG. 8 are plan views of a portion of a display panel according to embodiments of the present disclosure.

FIG. 9 is a cross-sectional view of a display panel according to embodiments of the present disclosure.

FIG. 10 is a detailed cross-sectional view of a display panel according to embodiments of the present disclosure, taken along the A-B cutting line of FIG. 6.

FIG. 11 is an enlarged cross-sectional view of a first sub-pixel of a display panel according to embodiments of the present disclosure.

FIG. 12 is an equivalent circuit of a sub-pixel of a display panel according to embodiments of the present disclosure.

FIG. 13 illustrates an optical touch sensing structure of a display device according to embodiments of the present disclosure.

FIG. 14 is a diagram illustrating an optical driving area and an optical sensing area configured in units of cells in a display device according to embodiments of the present disclosure.

FIG. 15 is a diagram illustrating an optical driving area and an optical sensing area configured in units of sub-cells in a display device according to embodiments of the present disclosure.

FIGS. 16A to 16H are examples of configuring an optical driving area and an optical sensing area in a display device according to embodiments of the present disclosure.

FIG. 17 illustrates an example of a first sub-cell included as an optical driving sub-cell in an optical driving area and a second sub-cell included as an optical sensing sub-cell in an optical sensing area in a display device according to embodiments of the present disclosure.

FIG. 18 illustrates an example of a first sub-cell included as an optical driving sub-cell in an optical driving area in a display device according to embodiments of the present disclosure.

FIG. 19 illustrates a second sub-cell included as an optical sensing sub-cell in an optical sensing area in a display device according to embodiments of the present disclosure.

FIG. 20 illustrates a first sub-cell included as an optical driving sub-cell in an optical driving area in a display device according to embodiments of the present disclosure.

FIG. 21 illustrates a second sub-cell included as an optical sensing sub-cell in an optical sensing area in a display device according to embodiments of the present disclosure.

FIG. 22 illustrates an optical touch sensing system of a display device according to embodiments of the present disclosure.

FIG. 23 is a cross-sectional view of an optical driving area and an optical sensing area in a display panel according to embodiments of the present disclosure.

FIGS. 24 to 26 are driving timing diagrams of a display device according to embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, when a detailed description of well-known functions or configurations related to this document is determined to unnecessarily cloud a gist of the inventive concept, the detailed description thereof will be omitted or can be briefly discussed. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

The advantages and features of the present disclosure and the method for achieving them will become clear with reference to the embodiments described in detail below together with the accompanying drawings. However, the present disclosure is not limited to the embodiments disclosed below, but can be implemented in various different forms, and these embodiments are provided only to make the disclosure of the present disclosure complete and to fully inform a person having ordinary skill in the art to which the present disclosure belongs of the scope of the disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products

The shapes, sizes, ratios, angles, numbers, etc. disclosed in the drawings for explaining the embodiments of this disclosure are examples, and therefore this disclosure is not limited to the matters illustrated. In assigning reference numerals to components of each drawing, the same components can be assigned the same numerals even when they are shown on different drawings. When determined to make the subject matter of the disclosure unclear, the detailed of the known art or functions can be skipped. As used herein, when a component “includes,” “has,” or “is composed of” another component, other components can be added unless “only” is used. When a component is expressed in the singular, it includes cases where the plural is included unless otherwise explicitly stated.

In interpreting a component, even if there is no separate explicit description of the error range, it is interpreted as including the error range.

Any implementation described herein as an “example” is not necessarily to be construed as preferred or advantageous over other implementations.

In describing a temporal relationship, when the temporal order is described as, for example, “after,” “subsequent,” “next,” and “before,” a case that is not continuous can be included unless a more limiting term, such as “just,” “immediate(ly),” or “direct(ly)” is used.

In the case of a description of a positional relationship, for example, if the positional relationship between two parts is described as “on,” “over,” “below,” “next to,” or “adjacent,” one or more other parts can be located between the two parts unless “directly,” or “nearly,” are used.

Although the terms first, second, etc. are used to describe various elements, these components are not limited by these terms. These terms are only used to distinguish one component from another. Therefore, the first element mentioned below can also be the second element within the technical scope of this disclosure.

In describing the components of this disclosure, terms such as first, second, A, B, (a), or (b) can be used. These terms are only intended to distinguish the components from other components, and the nature, order, sequence, or number of the components are not limited by the terms.

If a component is described as being “connected,” “coupled,” “linked,” or “attached,” to another component, it should be understood that the component can be directly connected, coupled, linked, or attached to the other component, but that other components can be interposed between each component that can be indirectly connected, coupled, linked, or attached without any specific explicit description.

When a component or layer is described as being “contacted,” or “overlapping,” to another component or layer, it should be understood that the component or layer can directly contact or overlap the other component or layer, but that other components can be interposed between each component that can be indirectly contacted or overlapped without any specific explicit description.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

“At least one” should be understood to include any combination of one or more of the associated components. For example, “at least one of the first, second, and third components” can be interpreted to include not only the first, second, or third components, but also any combination of two or more of the first, second, and third components.

“First direction,” “Second direction,” “Third direction,” “X-axis direction,” “Y-axis direction,” and “Z-axis direction” should not be interpreted as merely geometric relationships in which the relationship between them is perpendicular to each other, but can mean a wider directionality within the range in which the configuration of the present disclosure can function functionally.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings and coverages of the term “may” and vice versa.

Rather, these embodiments can be provided so that this disclosure can be sufficiently thorough and complete to assist those skilled in the art to fully understand the scope of the present disclosure. Furthermore, the present disclosure is only defined by scopes of claims.

Each feature of the various embodiments of the present disclosure can be partially or wholly combined or combined with each other, and various technical connections and operations are possible, and each embodiment can be implemented independently of each other or can be implemented together in a related relationship.

Hereinafter, various embodiments of the disclosure are described in detail with reference to the accompanying drawings. All the components of each display device according to all embodiments of the present disclosure are operatively coupled and configured.

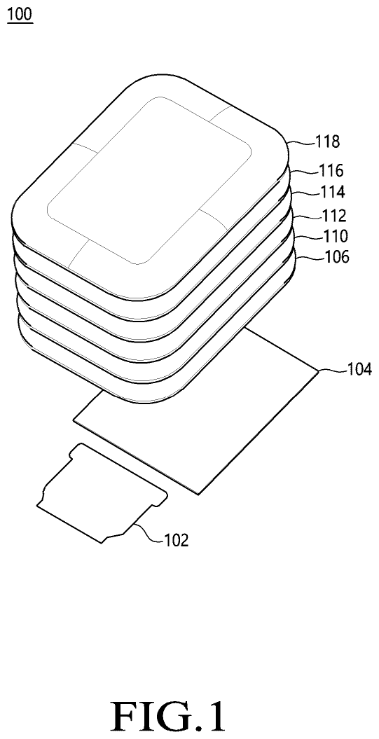

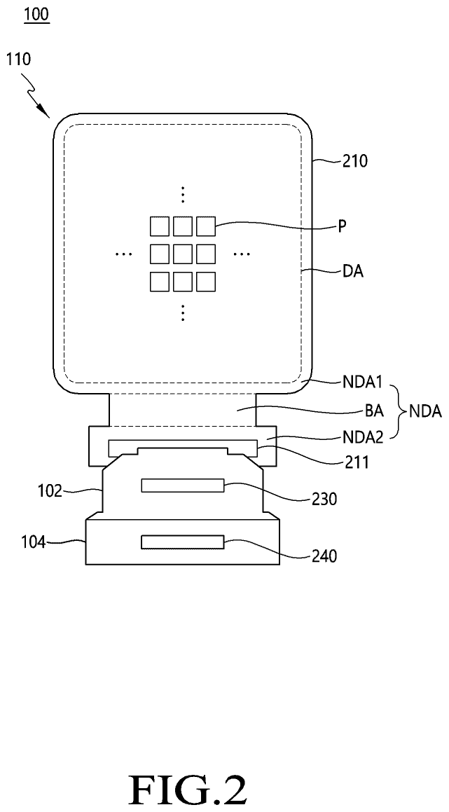

FIG. 1 illustrates a display device 100 according to embodiments of the present disclosure, and FIG. 2 is a plan view of the display device 100 according to embodiments of the present disclosure.

Referring to FIGS. 1 and 2, the display device 100 according to the embodiments of the present disclosure can include a display panel 110, a cover member 118 disposed on the display panel 110, a flexible printed circuit 102 connected to the display panel 110, and a printed circuit board 104 connected to the flexible printed circuit 102.

The display device 100 according to the embodiments of the present disclosure can further include a support substrate 106 disposed under the display panel 110 and supporting the lower portion of the display panel 110, a polarizing layer 114 disposed on the display panel 110, a first adhesive layer 112 disposed between the display panel 110 and the polarizing layer 114, and a second adhesive layer 116 disposed between the polarizing layer 114 and the cover member 118.

The display panel 110 can include a substrate 210. The substrate 210 can be a member on which various components such as a plurality of metal layers and a plurality of insulating material layers are formed. The substrate 210 can be made of an insulating material. For example, the substrate 210 can be made of glass or resin. In addition, the substrate 210 can be made of a flexible material. For example, the substrate 210 can be made of a flexible plastic material such as polyimide (PI).

The display panel 110 can display information, images, and/or images provided to a user. For example, the display panel 110 can include a display area DA and a non-display area NDA. For example, the substrate 210 can include a display area DA and a non-display area NDA. The display area DA and the non-display area NDA are not limited to the substrate 210, but can be described throughout the entire display device 100.

The display area DA can be an area where an image is displayed. The display area DA can include a plurality of pixels P. Each of the plurality of pixels P can be composed of a plurality of sub-pixels. At least one light emitting device can be arranged in each of the plurality of sub-pixels. The light emitting device can be configured differently depending on the type of the display device 100. For example, if the display device 100 is an inorganic light emitting display device, the light emitting device can be an inorganic-based light emitting device, such as a light emitting diode (LED), a micro LED, or a mini LED.

The non-display area NDA can be an area where an image is not displayed. In the non-display area NDA, various wirings, and circuits for driving a plurality of pixels P of the display area DA can be arranged. For example, various driving circuits and various wirings can be arranged in the non-display area NDA, and a pad section 211 to which an integrated circuit and a printed circuit are connected can be arranged.

For example, the driving circuit can include a data driving circuit and/or a gate driving circuit, but the embodiments of the present disclosure are not limited thereto. Wires or lines supplied with a control signal for controlling the driving circuit can be arranged on the substrate 210. For example, the control signal can include various timing signals including a clock signal, an input data enable signal, and synchronization signals, but the embodiments of the present disclosure are not limited thereto. The control signal can be supplied to the substrate 210 from the outside of the substrate 210 through the pad section 211. For example, circuit components such as a flexible printed circuit 102 and a printed circuit board 104 can be connected to the pad section 211.

The non-display area NDA can include a first non-display area NDA1, a bending area BA, and a second non-display area NDA2. For example, the first non-display area NDA1 can be an area surrounding at least a portion of the display area DA. The bending area BA can be an area extending from at least one of a plurality of sides of the first non-display area NDA1 and can be a bendable area. The second non-display area NDA2 can be an area extending from the bending area BA and can include a pad section 211. For example, the bending area BA can be in a bent state, and the remaining area of the substrate 210 excluding the bending area BA can be in a flat state. In this case, as the bending area BA is bent, the second non-display area NDA2 can be located on the back surface of the display area DA.

The display area DA of the substrate 210 or the display device 100 can be configured in various shapes according to the design of the display device 100. For example, the display area DA can be configured in a rectangular shape with four corners formed in a round shape, a rectangular shape with four corners formed in a right angle shape, or a circular shape.

A width of the second non-display area NDA2 where the pad section 211 is arranged can be wider than a width of the bending area BA. In addition, a width of the display area DA can be wider than the width of the bending area BA. In the drawing, the width of the bending area BA is depicted as being narrower than the width of other areas of the substrate 210, but the shape of the substrate 210 including the bending area BA is an example, and the embodiments of the present disclosure are not limited thereto.

The flexible printed circuit 102 and a printed circuit board 104 can be disposed at a lower portion of the display panel 110. For example, the flexible printed circuit 102 and the printed circuit board 104 can be arranged at one edge of the display panel 100. One side of the flexible printed circuit 102 can be connected to the display panel 110, and the other side can be connected to the printed circuit board 104. The flexible printed circuit 102 can be a flexible film.

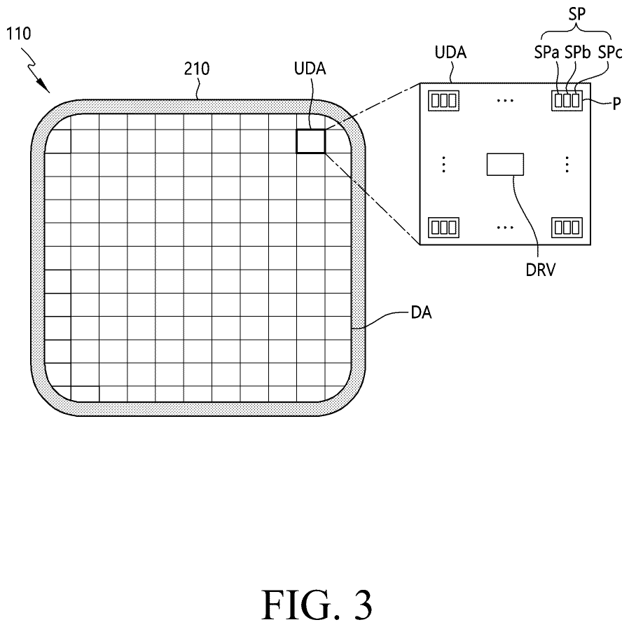

The pad section 211 disposed in the second non-display area NDA2 includes a plurality of pads, and a driving component including one or more flexible printed circuits 102 and a printed circuit board 104 can be attached or bonded. The plurality of pads included in the pad section 211 are electrically connected to one or more flexible printed circuits 102, and can transmit various signals (or power) from the printed circuit board 104 and one or more flexible printed circuits 102 to a driving circuit (for example, a driver DRV of FIG. 3) arranged in the display area DA.

The flexible printed circuit 102 can be a film in which various components are arranged on a flexible base film. For example, a first circuit component 230, such as a gate drive integrated circuit and/or a data drive integrated circuit, can be arranged on one or more flexible printed circuits 102. The first circuit component 230 can be a component that processes data and a driving signal for displaying an image. The flexible printed circuit 102 can be attached or bonded to a plurality of pads through a conductive adhesive layer.

The printed circuit board 104 can be a component that is electrically connected to the flexible printed circuit 102 and supplies a signal to the first circuit component 230. The printed circuit board 104 can be arranged on one side of the flexible printed circuit 102 and can be electrically connected to the flexible printed circuit 102. Various components for supplying various signals to the first circuit component 230 can be arranged on the printed circuit board 104. For example, various second circuit components 240, such as a timing controller, a power supply, a memory, or a processor, can be arranged on the printed circuit board 104. For example, the second circuit components 240 arranged on the printed circuit board 104 can include a timing controller and/or a power management integrated circuit (PMIC).

The printed circuit board 104 can include at least one hole, but the embodiments of the present disclosure are not limited thereto. An internal component (e.g., light sensor or temperature sensor) detecting ambient light or temperature can be arranged in an area corresponding to at least one hole (e.g., transmission hole).

A polarizing layer 114 can be arranged on a display panel 110 and can prevent or reduce light generated from an external light source from entering the display panel 110 and affecting a light emitting device.

A cover member 118 can be arranged on a polarizing layer 114 and can be a member for protecting the display panel 110.

A second adhesive layer 116 can be disposed between the polarizing layer 114 and the cover member 118. The second adhesive layer 116 can attach the cover member 118 to the display panel 110 or the polarizing layer 114. A first adhesive layer 112 can be disposed between the display panel 110 and the polarizing layer 114. The first adhesive layer 112 can attach the polarizing layer 114 to the display panel 110. The first adhesive layer 112 can be omitted. Each of the first adhesive layer 112 and the second adhesive layer 116 can include an optically clear adhesive (OCA), an optically clear resin (OCR), or a pressure sensitive adhesive PSA.

The support substrate 106 is disposed between the display panel 110 and the printed circuit board 104 to reinforce the rigidity of the display panel 110. The support substrate 106 can be a back plate.

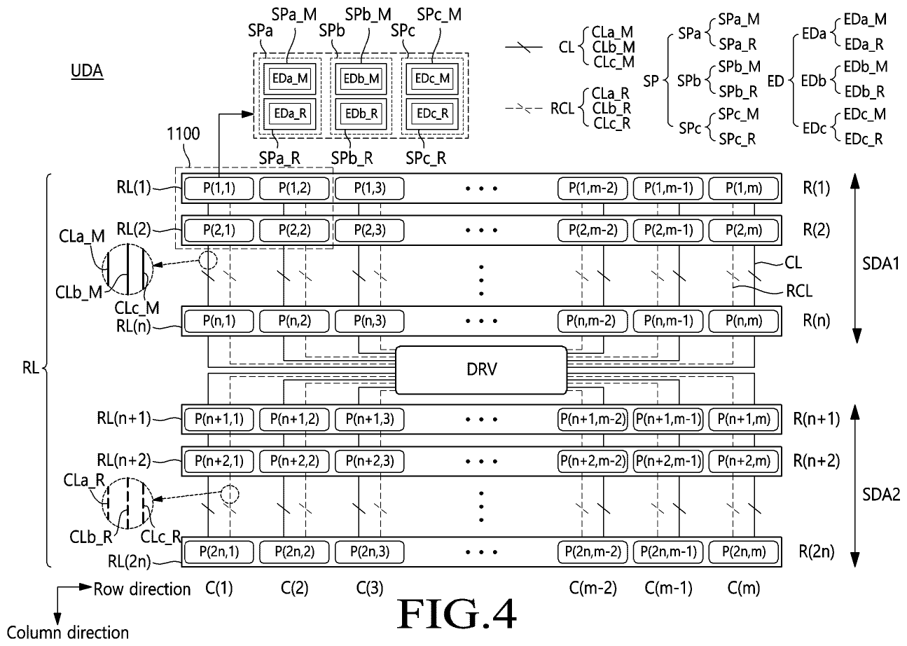

FIG. 3 is a plan view of a display panel 110 according to embodiments of the present disclosure, and FIG. 4 is a plan view of a unit driving area UDA of the display panel 110 according to embodiments of the present disclosure.

Referring to FIG. 3, the display area DA of the display panel 110 according to the embodiments of the present disclosure can include a plurality of unit driving areas UDA.

The display panel 110 can include a plurality of drivers DRV. The plurality of drivers DRV can be arranged in each of the plurality of unit driving areas UDA. For example, one driver DRV can be disposed in one unit driving area UDA. Each of the plurality of unit driving areas UDA can be a driving area driven by one driver DRV. For example, the driver DRV can be a driving chip manufactured using a MOSFET (Metal-oxide-silicon field effect transistor) manufacturing process on a semiconductor substrate. The display panel 110 can include a substrate 210 including a display area DA, and a plurality of pixels P arranged in a matrix form in the display area DA.

A plurality of pixels P can be arranged in each of the plurality of unit driving areas UDA. Each of the plurality of pixels P can include a plurality of sub-pixels SP. Each of the plurality of sub-pixels SP can include at least one light emitting device.

For example, the plurality of sub-pixels SP can include a first sub-pixel SPa, a second sub-pixel SPb, and a third sub-pixel SPc. The first sub-pixel SPa can include a first light emitting device that emits a first color light, the second sub-pixel SPb can include a second light emitting device that emits a second color light, and the third sub-pixel SPc can include a third light emitting device that emits a third color light. For example, the first color light, the second color light, and the third color light can be red light, green light, and blue light, respectively.

The display panel 110 can include a plurality of row lines RL and a plurality of column lines CL. Each of the plurality of row lines RL can be arranged to extend in a row direction. The plurality of row lines RL can be electrically connected to a first electrode of each of a plurality of light emitting devices ED. Each of the plurality of column lines CL can be arranged to extend in a column direction. The plurality of column lines CL can be electrically connected to a second electrode of each of the plurality of light emitting device ED.

For example, the first electrode of each of the plurality of light emitting device ED can be an anode electrode, and the second electrode of each of the plurality of light emitting device ED can be a cathode electrode. For another example, the first electrode of each of the plurality of light emitting device ED can be a cathode electrode, and the second electrode of each of the plurality of light emitting device ED can be an anode electrode.

Each of the plurality of row lines RL can be electrically connected to the second electrode of each of the plurality of light emitting device ED. For example, the second electrodes of each of the plurality of light emitting device ED can be commonly connected to one row line RL.

Each of the plurality of column lines CL can be electrically connected to the first electrode of each of the plurality of light emitting device ED. For example, the first electrode of each of the plurality of light emitting device ED can be commonly connected to one column line CL.

For example, the line width of each of the plurality of row lines RL can be greater than the line width of each of the plurality of column lines CL.

Referring to FIG. 4, the plurality of drivers DRV can drive the plurality of light emitting device ED, the plurality of column lines CL, and the plurality of row lines RL.

Each of the plurality of drivers DRV can drive a plurality of row lines RL and a plurality of column lines CL arranged in a corresponding unit driving area UDA among the plurality of unit driving areas UDA, thereby emitting light from a plurality of light emitting device ED arranged in the corresponding unit driving area UDA.

The plurality of drivers DRV can be built into the display panel 110. The plurality of drivers DRV can be disposed in the display area DA, and can be arranged on the substrate 210. The plurality of drivers DRV can be disposed to correspond to a plurality of unit driving areas UDA. For example, one driver DRV can be disposed in one unit driving area UDA.

The plurality of drivers DRV are disposed in the display area DA, and can be positioned closer to the substrate 210 than the plurality of light emitting device ED.

For example, the plurality of row lines RL can be driven sequentially. For another example, the plurality of row lines RL can be driven simultaneously. For another example, two or more row lines RL among the plurality of row lines RL can be driven simultaneously.

For example, during a specific display driving period, among the plurality of row lines RL arranged in the unit driving area UDA, at least one row line RL can be driven, and the remaining row lines RL may not be driven.

A voltage applied to the row line RL can be referred to as a low-potential voltage, and the low-potential voltage can also be referred to as a row line voltage or a cathode voltage. The low-potential voltage can have various voltage values depending on the driving type or driving state. For example, the low-potential voltage can include a first low-potential voltage, a second low-potential voltage, and a third low-potential voltage.

Driving the row line RL can mean that the first low-potential voltage is supplied to the row line RL. Not driving the row line RL can mean that the second low-potential voltage higher than the first low-potential voltage is supplied to the row line RL. Accordingly, the light emitting device ED overlapping with the driven row line RL can emit light, and the light emitting device ED overlapping with the non-driven row line RL may not emit light.

The structure of one unit driving area UDA will be described in more detail with reference to FIG. 4.

As an example, one unit driving area UDA can be divided into a first sub-driving area SDA1 and a second sub-driving area SDA2. As another example, one unit driving area UDA can be divided into three or more sub-driving areas. As another example, one unit driving area UDA may not be divided into two or more sub-driving areas.

One unit driving area UDA can include one driver DRV and (2n×m) pixels P(1, 1), . . . , P(1, m), P(2, 1 ), . . . , P(2, m), . . . , P(2n, 1), . . . , P(2n, m) driven by one driver DRV.

In the embodiments of the present disclosure, n can be a sequence number of a row, or the number of rows in each of the first sub-driving area SDA1 and the second sub-driving area SDA2, or the number of row lines RL in each of the first sub-driving area SDA1 and the second sub-driving area SDA2, or the number of pixel rows in each of the first sub-driving area SDA1 and the second sub-driving area SDA2. m can be a sequence number of a column, or the number of columns in each of the first sub-driving area SDA1 and the second sub-driving area SDA2, or the number of column lines CL in each of the first sub-driving area SDA1 and the second sub-driving area SDA2, or the number of pixel columns in each of the first sub-driving area SDA1 and the second sub-driving area SDA2. In the embodiments of the present disclosure, n can be a natural number greater than or equal to 1, and m can be a natural number greater than or equal to 1.

Further, (2n×m) pixels P(1, 1), . . . , P(1, m), P(2, 1), . . . , P(2, m), . . . , P(2n, 1), . . . , P(2n, m) can be arranged in 2n rows R(1), . . . , R(2n) and m columns C(1), . . . , C(m).

Among (2n×m) pixels P(1, 1), . . . , P(1, m), P(2, 1), . . . , P(2, m), . . . , P(2n, 1), . . . , P(2n, m), (n×m) pixels P(1, 1), . . . , P(1, m), P(2, 1), . . . , P(2, m), . . . , P(n, 1), . . . , P(n, m) arranged in the first to n-th rows R(1), . . . , R(n) can be arranged in the first sub-driving area SDA1.

Among (2n×m) pixels P(1, 1), . . . , P(1, m), P(2, 1), . . . , P(2, m), . . . , P(2n, 1), . . . , P(2n, m), (n×m) pixels P(n+1, 1), . . . , P(n+1, m), P(n+2, 1), . . . , P(n+2, m), . . . , P(2n, 1), . . . , P(2n, m) arranged in the (n+1)-th to the 2n-th row R(n+1), . . . , R(2n) can be arranged in the second sub-driving area SDA2.

One unit driving area UDA can include 2n row lines RL(1), . . . , RL(2n) to drive (2n×m) pixels P(1, 1), . . . , P(1, m), P(2, 1), . . . , P(2, m), . . . , P(2n, 1), . . . , P(2n, m).

Among the 2n row lines RL(1 ), ..., RL(2n), the first to n-th row lines R(1), ..., RL(n) can be arranged in the first sub-driving area SDA1. Among the 2n row lines RL(1 ),. RL(2n), the (n+1)-th to the 2n-th row lines R(n+1),. R(2n) can be arranged in the second sub-driving area SDA2.

Each of the 2n row lines RL(1), . . . RL(2n) can overlap with m pixels. For example, the first row line RL(1) can overlap with m pixels P(1, 1), . . . P(1, m) arranged in the first row R(1). The n-th row line RL(n) can overlap with m pixels P(n, 1), . . . P(n, m) arranged in the n-th row (R(n)). The (n+1)-th row line RL(n+1) can overlap with the m pixels P(n+1, 1), . . . P(n+1, m) arranged in the (n+1)-th row R(n+1). The 2n-th row line RL(2n) can overlap with the m pixels P(2n, 1), . . . P(2n, m) arranged in the 2nth row R(2n).

For example, each of the m pixels P(n, 1), . . . P(n, m) can include k sub-pixels SPa, SPb and SPc.

A first sub-pixel SPa can include a first light emitting device EDa that emits a first color light. The first sub-pixel SPa can include at least one of a first main sub-pixel SPa_M and a first redundancy sub-pixel SPa_R. The first light emitting device EDa included in the first sub-pixel SPa can include at least one of a first main light emitting device EDa_M included in the first main sub-pixel SPa_M and a first redundancy light emitting device EDa_R included in the first redundancy sub-pixel SPa_R.

A second sub-pixel SPb can include a second light emitting device EDb that emits a second color light. The second sub-pixel SPb can include at least one of the second main sub-pixel SPb_M and the second redundancy sub-pixel SPb_R. The second light emitting device EDb included in the second sub-pixel SPb can include at least one of the second main light emitting device EDb_M included in the second main sub-pixel SPb_M and the second redundancy light emitting device EDb_R included in the second redundancy sub-pixel SPb_R.

A third sub-pixel SPc can include a third light emitting device EDc that emits third color light. The third sub-pixel SPc can include at least one of the third main sub-pixel SPc_M and the third redundancy sub-pixel SPc_R. The third light emitting device EDc included in the third sub-pixel SPc can include at least one of the third main light emitting device EDc_M included in the third main sub-pixel SPc_M and the third redundancy light emitting device EDc_R included in the third redundancy sub-pixel SPc_R. Each row line of a row can be connected to k sub-pixels SPa, SPb and SPc included in each of m pixels arranged in the corresponding row. More specifically, each row line can be connected to second electrodes of k light emitting devices EDa, EDb and EDc included in each of m pixels arranged in the corresponding row.

For example, the first row line RL(1) can be connected to k sub-pixels SPa, SPb and SPc included in each of m pixels P(1, 1), . . . P(1, m) arranged in the first row R(1). More specifically, the first row line RL(1) can be connected to the second electrodes of k light emitting devices EDa, EDb and EDc included in each of m pixels P(1, 1), . . . P(1, m) arranged in the first row R(1).

Referring to FIG. 4, one unit driving area UDA can include (m×k×2) (main) column lines CLa_M, CLb_M and CLc_M to drive (2n×m) pixels P(1, 1), . . . , P(1, m), P(2, 1), . . . , P(2, m), . . . , P(2n, 1), . . . , P(2n, m), and in some cases, can further include (m×k×2) redundancy column lines CLa_R, CLb_R and CLc_R. Here, k is the number of sub-pixels SP included in one pixel P. In the example of FIG. 4, k is 3. For example, one pixel P can include three sub-pixels SPa, SPb and SPc.

Each of the (m×k×2) (main) column lines CLa_M, CLb_M and CLc_M can be commonly connected to first electrodes of a plurality of main light emitting devices arranged in the same column. Each of the (m×k×2) redundancy column lines CLa_R, CLb_R and CLc_R can be commonly connected to first electrodes of a plurality of redundancy light emitting devices arranged in the same column.

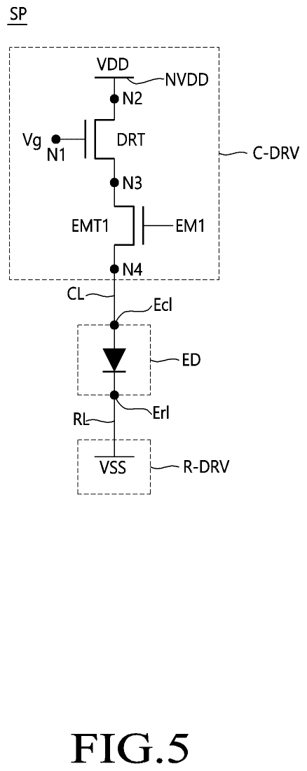

FIG. 5 illustrates a sub-pixel SP of a display panel 110 according to embodiments of the present disclosure.

Referring to FIG. 5, the sub-pixel SP according to embodiments of the present disclosure can include a light emitting device ED including a first electrode Ecl and a second electrode Erl, a column driver C-DRV for driving a column line CL electrically connected to the first electrode Ecl of the light emitting device ED, and a row driver R-DRV for driving a row line RL electrically connected to the second electrode Erl of the light emitting device ED.

The light emitting device ED can include a first electrode Ecl and a second electrode Erl. The first electrode Ecl can be electrically connected to a column line CL, and the second electrode Erl can be electrically connected to a row line RL. For example, the first electrode Ecl can be an anode electrode, and the second electrode Erl can be a cathode electrode. For another example, the first electrode Ecl can be a cathode electrode, and the second electrode Erl can be an anode electrode.

The column driver C-DRV included in a unit driving area UDA can be connected to a plurality of column lines CL included in the unit driving area UDA, and can drive a plurality of column lines CL included in the unit driving area UDA. Each of the plurality of column lines CL can be commonly connected to the first electrode Ecl of each of the plurality of light emitting devices ED included in the plurality of sub-pixels SP arranged in the corresponding column.

The row driver R-DRV included in a unit driving area UDA can be connected to a plurality of row lines RL included in the unit driving area UDA and can drive a plurality of row lines RL included in the unit driving area UDA. Each of the plurality of row lines RL can be commonly connected to a second electrode Erl of each of a plurality of light emitting devices ED included in a plurality of sub-pixels SP arranged in the corresponding row.

The column driver C-DRV can include main nodes including a first node N1, a second node N2, a third node N3, and a fourth node N4. The column driver C-DRV can include a driving transistor DRT and a first emission control transistor EMT1.

The first node N1 can be a node to which a voltage Vg for controlling the on-off of the driving transistor DRT is applied. The second node N2 can be a node electrically connected to a high-potential voltage node NVDD to which a high-potential voltage VDD is applied. The third node N3 can be a node to which the driving transistor DRT and the first emission control transistor EMT1 are connected. The fourth node N4 can be a node to which the first emission control transistor EMT1 and the light emitting device ED are electrically connected, and can be a node to which the column line CL is electrically connected. Here, a source electrode or a drain electrode of the first emission control transistor EMT1 and the first electrode Ecl of the light emitting device ED can be commonly connected to the column line CL.

The driving transistor DRT supplies a driving current to make the light emitting device ED emit light, is connected between the second node N2 and the third node N3, and can control the connection between the second node N2 and the third node N3 according to the voltage of the first node N1.

The gate electrode of the driving transistor DRT is electrically connected to the first node N1, and a gate voltage Vg can be applied thereto. The drain electrode or the source electrode of the driving transistor DRT can be electrically connected to the second node N2. The source electrode or the drain electrode of the driving transistor DRT can be electrically connected to the third node N3.

The first emission control transistor EMT1 can control a connection of a path through which the driving current flows, and can play a role in controlling an emission of the light emitting device ED.

If the driving transistor DRT and the first emission control transistor EMT1 are turned on between a high-potential voltage VDD and a low-potential voltage VSS, the driving current can be supplied to the light emitting device ED through the driving transistor DRT and the first emission control transistor EMT1. Accordingly, the light emitting device ED can emit light.

The first emission control transistor EMT1 is connected between the third node N3 and the fourth node N4, and can control the connection between the third node N3 and the fourth node N4 according to a first emission control signal EM1. The first emission control signal EM1 can be applied to the gate electrode of the first emission control transistor EMT1. The drain electrode or the source electrode of the first emission control transistor EMT1 can be electrically connected to the third node N3. The source electrode or drain electrode of the first emission control transistor EMT1 can be electrically connected to the fourth node N4.

The first emission control signal EM1 can be a pulse width modulation signal that varies at a predefined time (for example, each frame, or each sub-frame included in one frame), but the embodiments of the present disclosure are not limited thereto.

The first emission control signal EM1 can be generated by the driver DRV, or can be supplied to the driver DRV from a driving-related circuit such as a timing controller. For example, if the first emission control signal EM1 is a pulse width modulation signal, the first emission control signal EM1 can have a pulse width corresponding to an image signal (e.g., data voltage, data signal). For example, if the pulse width of the first t emission control signal EM1 is large, the luminance of the light emitting device ED can be high. If the pulse width of the first emission control signal EM1 is small, the luminance of the light emitting device ED can be low.

The row driver R-DRV can drive at least one row line RL by supplying a low-potential voltage VSS to at least one row line RL.

The row driver R-DRV can perform display-on driving or display-off driving for one row line RL. The row driver R-DRV can supply a low-potential voltage for display-on driving to one row line RL in order to perform display-on driving for one row line RL. The row driver R-DRV can supply a low-potential voltage for display-off driving to one row line RL in order to perform display-off driving for one row line RL.

A low-potential voltage for display-on driving and a low-potential voltage for display-off driving can be different. For example, the low-potential voltage for display-on driving can be lower than the low-potential voltage for display-off driving. In the embodiments of the present disclosure, the “low-potential voltage for display-on driving” is also referred to as the “first low-potential voltage,” and the “low-potential voltage for display-off driving” is also referred to as the “second low-potential voltage.”

The column driver C-DRV can further include at least one switching element and/or at least one transistor in addition to the driving transistor DRT and the first emission control transistor EMT1. Each of the transistors included in the column driver C-DRV can be an n-type transistor or a p-type transistor.

The column driver C-DRV can further include at least one capacitor. The column driver C-DRV can further include at least one circuit element. For example, the at least one circuit element can include a power output buffer.

The row driver R-DRV can include at least one switching element and/or at least one transistor. Each of the transistors included in the row driver R-DRV can be an n-type transistor or a p-type transistor. The row driver R-DRV can further include at least one circuit element. For example, at least one circuit element can include a power output buffer.

A part or all of the column driver C-DRV and the row driver R-DRV can be internal circuits included in the driver DRV. As another example, the column driver C-DRV and the row driver R-DRV may not be included in the driver DRV and can be circuits formed on the substrate 210 of the display panel 110.

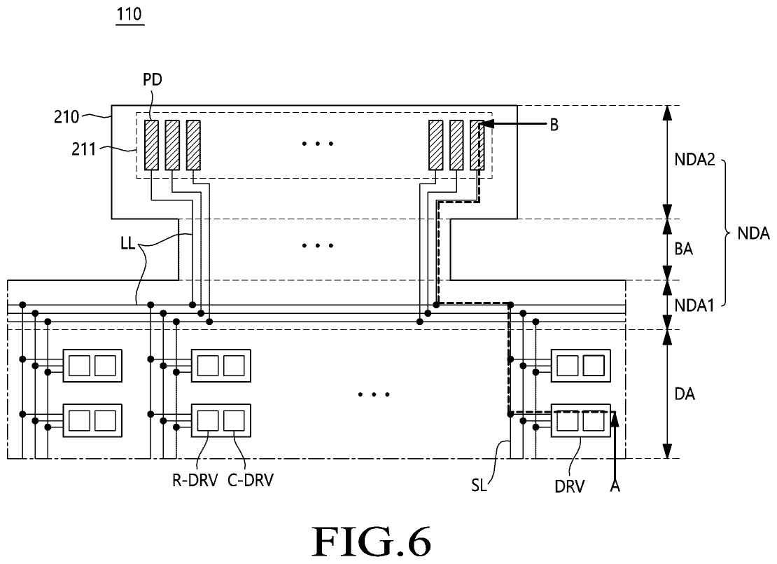

FIG. 6 is a plan view of the display panel 110 according to the embodiments of the present disclosure.

Referring to FIG. 6, the substrate 210 of the display panel 110 according to the embodiments of the present disclosure can include a display area DA and a non-display area NDA, and the non-display area NDA can include a first non-display area NDA1, a bending area BA, and a second non-display area NDA2.

A plurality of drivers DRV can be arranged in the display area DA. Each of the plurality of drivers DRV can be a circuit for driving light emitting devices of a plurality of sub-pixels included in a corresponding unit driving area (UDA of FIG. 4). Each of the plurality of drivers DRV can include a row driver R-DRV for driving a plurality of row lines and a column driver C-DRV for driving a plurality of column lines, in order to drive a plurality of light emitting devices ED included in a corresponding unit driving area (UDA of FIG. 4).

A pad section 211 including a plurality of pads PD can be disposed in the second non-display area NDA2.

A plurality of signal lines SL and a plurality of link lines LL for signal transmission between a plurality of drivers DRV arranged in the display area DA and the pad section 211 can be arranged on the substrate 210. The plurality of signal lines SL can be electrically connected between the plurality of link lines LL and the plurality of drivers DRV. The plurality of link lines LL can electrically connect the plurality of pads PD and the plurality of signal lines SL.

The plurality of link lines LL can be arranged in the non-display area NDA, and all or part of each of the plurality of signal lines SL can be arranged in the display area DA.

Each of the plurality of drivers DRV can receive various signals to perform a driving operation through the plurality of link lines LL and the plurality of signal lines SL. Here, the various signals can include various power voltages and various signals required for the driving operation of each of the plurality of drivers DRV.

As the bending area BA is bent, a portion of the plurality of link lines LL can also be bent. Stress can be concentrated on a portion of the bent link line LL, and thus cracks can occur in the link line LL. Accordingly, the plurality of link lines LL can be formed of a conductive material having excellent ductility to reduce cracks when the bending area BA is bent. In addition, the plurality of link lines LL can be composed of one of various conductive materials used in the display area DA. The plurality of link lines LL can be composed of a multilayer structure including various conductive materials. The plurality of link lines LL can be composed of various shapes to reduce stress. At least a portion of the plurality of link lines LL arranged on the bending area BA can extend in the same direction as the extension direction of the bending area BA, or can extend in a direction different from the extension direction of the bending area BA to reduce stress.

Hereinafter, in order to examine the planar structure of the display panel 110 according to the embodiments of the present disclosure in more detail, it will be described a planar structure of a portion 1100 of the planar view of FIG. 4 in more detail as an example.

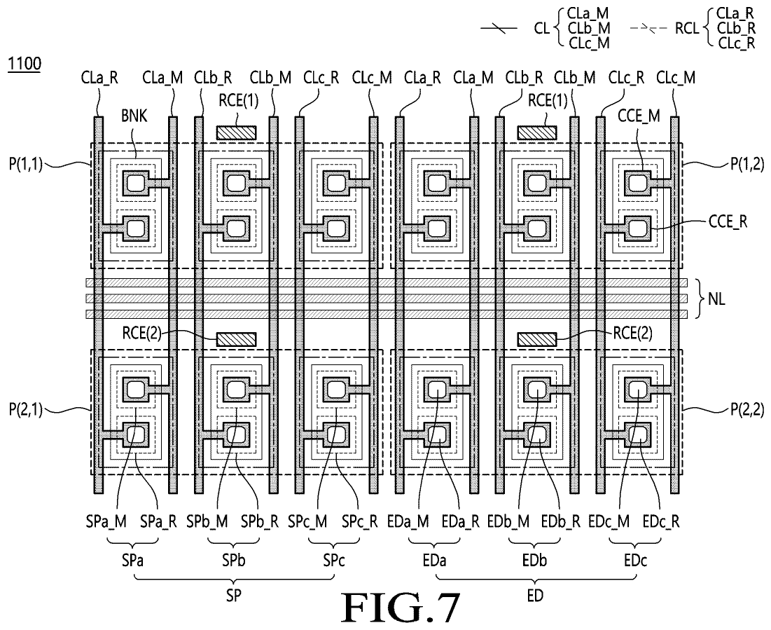

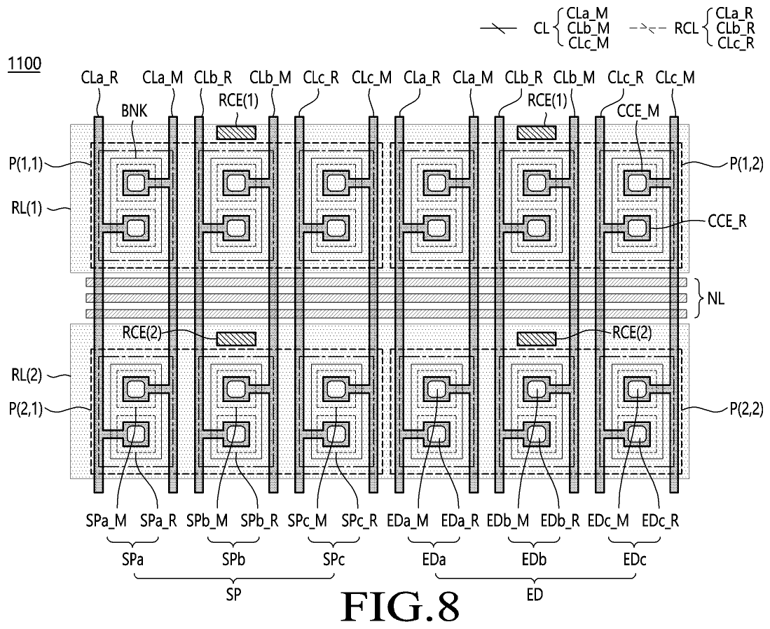

FIG. 7 and FIG. 8 are plan views of a portion 1100 of a display panel 110 according to embodiments of the present disclosure. FIG. 7 and FIG. 8 are enlarged plan views of a portion 1100 of the plan view of FIG. 4, and are enlarged plan views of a two-row, two-column area 1100.

FIG. 7 is a plan view that does not represent two row lines RL(1) and RL(2) arranged in a two-row, two-column area 1100, and FIG. 8 is a plan view that adds two row lines RL(1) and RL(2) arranged in a two-row, two-column area 1100 to the plan view of FIG. 8.

In the two-row, two-column area 1100, four pixels P(1,1), P(1,2), P(2,1), P(2,2) can be arranged in two rows and two columns. For example, in the two-row, two-column area 1100, two pixels P(1,1) and P(1,2) can be arranged in a first row (e.g., a first pixel row), and two pixels P(2,1) and P(2,2) can be arranged in a second row (e.g., a second pixel row). In addition, two pixels P(1,1) and P(2,1) can be arranged in a first column (e.g., a first pixel column), and two pixels P(1,2) and P(2,2) can be arranged in a second column (e.g., a second pixel column).

In the two-row, two-column area 1100, each of the four pixels P(1,1), P(1,2), P(2,1) and P(2,2) arranged in two rows and two columns can include k sub-pixels. Here, k is the number of sub-pixels included in one pixel.

Referring to FIGS. 7 and 8, it is exemplified a case where k is 3 is as an example. Accordingly, in the two-row, two-column area 1100, each of the four pixels P(1,1), P(1,2), P(2,1) and P(2,2)) arranged in two rows and two columns can include three sub-pixels SPa, SPb and SPc. In the following description, it is described a case where k is 3.

The three sub-pixels can include a first sub-pixel SPa including a first light emitting device EDa that emits a first color light, a second sub-pixel SPb including a second light emitting device EDb that emits a second color light, and a third sub-pixel SPc including a third light emitting device EDc that emits a third color light.

If the display panel 110 according to the embodiments of the present disclosure has a redundancy structure, the sub-pixel redundancy structure is as follows. The first sub-pixel SPa can include a first main sub-pixel SPa_M including a first main light emitting device EDa_M and a first redundancy sub-pixel SPa_R including a first redundancy light emitting device EDa_R. The second sub-pixel SPb can include a second main sub-pixel SPb_M including a second main light emitting device EDb_M and a second redundancy sub-pixel SPb_R including a second redundancy light emitting device EDb_R. The third sub-pixel SPc can include a third main sub-pixel SPc_M including a third main light emitting device EDc_M and a third redundancy sub-pixel SPc_R including a third redundancy light emitting device EDc_R.

If the display panel 110 according to the embodiments of the present disclosure has a redundancy structure, the light emitting device redundancy structure is as follows. The first light emitting device EDa can include a first main light emitting device EDa_M that emits a first color light and a first redundancy light emitting device EDa_R that emits a first color light. The second light emitting device EDb can include a second main light emitting device EDb_M that emits a second color light and a second redundancy light emitting device EDb_R that emits a second color light. The third light emitting device EDb can include a third main light emitting device EDc_M that emits a third color light and a third redundancy light emitting device EDc_R that emits a third color light.

In the two-row, two-column area 1100, a first row line RL(1) and a second row line RL(2) can be arranged. The first row line RL(1) can be arranged in the first row (i.e., the first pixel row), and the second row line RL(2) can be arranged in the second row (i.e., the second pixel row).

In the area where the first row line RL(1) is arranged, there can be arranged a first main sub-pixel SPa_M, a first redundancy sub-pixel SPa_R, a second main sub-pixel SPb_M, a second redundancy sub-pixel SPb_R, a third main sub-pixel SPc_M, and a third redundancy sub-pixel SPc_R arranged in the first row (first pixel row).

The first row line RL(1) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

At least a portion of the first row line RL(1) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the first row (or the first pixel row).

In the area where the second row line RL(2) is arranged, there can be arranged a first main sub-pixel SPa_M, a first redundancy sub-pixel SPa_R, a second main sub-pixel SPb_M, a second redundancy sub-pixel SPb_R, a third main sub-pixel SPc_M, and a third redundancy sub-pixel SPc_R arranged in the second row (second pixel row).

The second row line RL(2) can be connected to the second electrode Erl of each of the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

At least a portion of the second row line RL(2) can overlap with the first main light emitting device EDa_M, the first redundancy light emitting device EDa_R, the second main light emitting device EDb_M, the second redundancy light emitting device EDb_R, the third main light emitting device EDc_M, and the third redundancy light emitting device EDc_R arranged in the second row (or the second pixel row).

A plurality of first column lines CL arranged in a first column (or first pixel column) can include a first main column line CLa_M that is commonly connected to a first main sub-pixel SPa_M included in each of two pixels P(1,1)and P(2,1) arranged in the first column (or first pixel column), and a first redundancy column line CLa_R that is commonly connected to a first redundancy sub-pixel SPa_R included in each of two pixels P(1,1) and P(2,1) arranged in the first column (or first pixel column).

The first main column line CLa_M arranged in the first column (or the first pixel column) can be commonly connected to the first electrodes Ecl of the two first main light emitting devices EDa_M arranged in the first column (or the first pixel column).

The first redundancy column line CLa_R arranged in the first column (or the first pixel column) can be commonly connected to the first electrodes Ecl of two first redundancy light emitting devices EDa_R arranged in the first column (or the first pixel column).

In addition, the plurality of first column lines CL arranged in the first column (or the first pixel column) can further include a second main column line CLb_M commonly connected to a second main sub-pixel SPb_M included in each of the two pixels P(1,1) and P(2,1) arranged in the first column (or the first pixel column), and a second redundancy column line CLb_R commonly connected to a second redundancy sub-pixel SPb_R included in each of the two pixels P(1,1) and P(2,1) arranged in the first column (or the first pixel column).

The second main column line CLb_M arranged in the first column (or the first pixel column) can be commonly connected to the first electrodes Ecl of the two second main light emitting devices EDb_M arranged in the first column (or the first pixel column).

The second redundancy column line CLb_R arranged in the first column (or the first pixel column) can be commonly connected to the first electrodes Ecl of the two second redundancy light emitting devices EDb_R arranged in the first column (or the first pixel column).

In addition, the plurality of first column lines CL arranged in the first column (or the first pixel column) can further include a third main column line CLc_M commonly connected to the third main sub-pixel SPc_M included in each of the two pixels P(1,1) and P(2,1) arranged in the first column (or the first pixel column), and a third redundancy column line CLc_R commonly connected to the third redundancy sub-pixel SPc_R included in each of the two pixels P(1,1) and P(2,1) arranged in the first column (or the first pixel column).

The third main column line CLc_M arranged in the first column (or the first pixel column) can be commonly connected to the first electrodes Ecl of the two third main light emitting devices EDc_M arranged in the first column (or the first pixel column).

The third redundancy column line CLc_R arranged in the first column (or the first pixel column) can be commonly connected to the first electrodes Ecl of two third redundancy light emitting devices EDc_R arranged in the first column (or the first pixel column).

A plurality of second column lines CL arranged in a second column (or second pixel column) can include a first main column line CLa_M that is commonly connected to a first main sub-pixel SPa_M included in each of two pixels P(1,2) and P(2,2) arranged in the second column (or second pixel column), and a first redundancy column line CLa_R that is commonly connected to a first redundancy sub-pixel SPa_R included in each of two pixels P(1,2) and P(2,2) arranged in the second column (or second pixel column).

The first main column line CLa_M arranged in the second column (or the second pixel column) can be commonly connected to the first electrodes Ecl of the two first main light emitting devices EDa_M arranged in the second column (or the second pixel column).

The first redundancy column line CLa_R arranged in the second column (or the second pixel column) can be commonly connected to the first electrodes Ecl of the two first redundancy light emitting devices EDa_R arranged in the second column (or the second pixel column).

In addition, the plurality of second column lines CL arranged in the second column (second pixel column) can further include a second main column line CLb_M commonly connected to a second main sub-pixel SPb_M included in each of two pixels P(1,2) and P(2,2) arranged in the second column (or second pixel column), and a second redundancy column line CLb_R commonly connected to a second redundancy sub-pixel SPb_R included in each of two pixels P(1,2) and P(2,2) arranged in the second column (or second pixel column).

The second main column line CLb_M arranged in the second column (or the second pixel column) can be commonly connected to the first electrodes Ecl of the two second main light emitting devices EDb_M arranged in the second column (or the second pixel column).

The second redundancy column line CLb_R arranged in the second column (or the second pixel column) can be commonly connected to the first electrodes Ecl of two second redundancy light emitting devices EDb_R arranged in the second column (or the second pixel column).

In addition, the plurality of first column lines CL arranged in the second column (or the second pixel column) can further include a third main column line CLc_M commonly connected to a third main sub-pixel SPc_M included in each of two pixels P(1,2) and P(2,2) arranged in the second column (or the second pixel column), and a third redundancy column line CLc_R commonly connected to a third redundancy sub-pixel SPc_R included in each of two pixels P(1,2) and P(2,2) arranged in the second column (or the second pixel column).

The third main column line CLc_M arranged in the second column (or the second pixel column) can be commonly connected to the first electrodes Ecl of the two third main light emitting devices EDc_M arranged in the second column (or the second pixel column).

The third redundancy column line CLc_R arranged in the second column (or the second pixel column) can be commonly connected to the first electrodes Ecl of two third redundancy light emitting devices EDc_R arranged in the second column (or the second pixel column).

The main column connection electrodes CCE_M and the redundancy column connection electrodes CCE_R arranged in the first column (or the first pixel column) can be disposed between the first main column line CLa_M and the first redundancy column line CLa_R.

The main column connection electrodes CCE_M and the redundancy column connection electrodes CCE_R arranged in the second column (or the second pixel column) can be disposed between the second main column line CLb_M and the second redundancy column line CLb_R.

The main column connection electrodes CCE_M and the redundancy column connection electrodes CCE_R arranged in the third column (or the third pixel column) can be disposed between the third main column line CLc_M and the third redundancy column line CLc_R.

The display panel 110 according to the embodiments of the present disclosure can further include at least one row connection electrode for electrically connecting each of the plurality of row lines RL to the driver DRV.

The display panel 110 according to the embodiments of the present disclosure can further include at least one first row connection electrode RCE(1) connected to a first row line RL(1) arranged in a first row (or a first pixel row), and at least one second row connection electrode RCE(2) connected to a second row line RL(2) arranged in a second row (or a second pixel row).

The first row line RL(1) can be vertically overlapped with at least one first row connection electrode RCE(1), and the second row line RL(2) can be vertically overlapped with at least one second row connection electrode RCE(2).

The first row line RL(1) can be electrically connected to the row driver R-DRV of the corresponding driver DRV through at least one first row connection electrode RCE(1). The second row line RL(2) can be electrically connected to the row driver R-DR of the corresponding driver DRV through at least one second row connection electrode RCE(2).

A bank BNK can be disposed in each of a plurality of sub-pixels SP. The plurality of banks BNK can be structures on which a plurality of light emitting devices ED are mounted. When manufacturing a panel, in a transfer process for transferring a plurality of light emitting devices ED to a display device 100, a plurality of banks BNK can guide the positions of the plurality of light emitting devices ED. For example, when manufacturing a panel, a plurality of light emitting devices ED can be transferred onto a plurality of banks BNK in a transfer process of the plurality of light emitting devices ED. The plurality of banks BNK can be an organic insulating layer, a bank pattern, or a structure, but the embodiments of the present disclosure are not limited thereto.

The banks BNK of each of the plurality of sub-pixels SP can be arranged to be spaced apart from each other. The banks BNK of each of the plurality of sub-pixels SP can be configured to be separated from each other. Accordingly, the banks BNK of the first sub-pixel SPa, the second sub-pixel SPb, and the third sub-pixel SPc to which different types of light emitting devices ED are transferred can be easily identified.

The bank BNK of the first main sub-pixel SPa_M and the bank BNK of the first redundancy sub-pixel SPa_R can be connected to each other, or can be formed spaced apart from each other or separately. For example, considering the design of the transfer process requirements, the bank BNK of the first main sub-pixel SPa_M and the bank BNK of the first redundancy sub-pixel SPa_R, in which light emitting devices EDa_M, EDa_R of the same type (for example, types that emit the same color light) are arranged, can be connected to each other, or can be formed spaced apart from each other or separately. In addition, the bank BNK of the second main sub-pixel SPb_M and the bank BNK of the second redundancy sub-pixel SPb_R can be connected to each other, or can be formed spaced apart from each other or separately. The bank BNK of the third main sub-pixel SPc_M and the bank BNK of the third redundancy sub-pixel SPc_R can be connected to each other, or can be formed to be spaced apart from each other or separated from each other.

The bank BNK of the first main sub-pixel SPa_M and the first redundancy sub-pixel SPa_R, the bank BNK of the second main sub-pixel SPb_M and the second redundancy sub-pixel SPb_R, and the bank BNK of the third main sub-pixel SPc_M and the third redundancy sub-pixel SPc_R can be formed in various ways, and the embodiments of the present disclosure are not limited thereto.

For example, the plurality of banks BNK can be formed of an organic insulating material. The plurality of banks BNK can be formed of a single layer or multiple layers of an organic insulating material. For example, the plurality of banks BNK can be composed of a photo resist, a polyimide (PI), or an acrylic material.

The plurality of row lines RL can be formed of a transparent conductive material, but the embodiments of the present disclosure are not limited thereto. The plurality of row lines RL can be composed of a transparent conductive material so that light emitted from the light emitting devices ED can be directed upward through the row lines RL. For example, the plurality of row lines RL can be composed of a transparent conductive material such as indium tin oxide (ITO), indium zinc oxide (IZO), indium gallium zinc oxide (IGZO), and the like.

The plurality of column lines CL can be made of a conductive material. For example, the plurality of column lines CL can be formed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), but the embodiments of the present disclosure are not limited thereto. For another example, the plurality of column lines CL can have a multilayer structure of conductive materials. For example, the plurality of column lines CL can be made of a multilayer structure of titanium (Ti)/aluminum (Al)/titanium (Ti)/indium tin oxide (ITO).

For example, if the light emitting device ED is a device manufactured through a semiconductor process, such as a micro LED, a plurality of light emitting devices ED can be formed on a wafer and the light emitting devices ED can be transferred to a substrate 210 of the display panel 110 to manufacture the display panel 110. In the process of transferring a plurality of light emitting devices ED having a microscopic size from the wafer to the substrate 210, various defects can occur. For example, a non-transfer defect can occur in which the light emitting device ED is not transferred in some sub-pixels SP, and a misalignment defect can occur in which the light emitting device ED is transferred out of its proper position due to an alignment error in other sub-pixels SP. In addition, the transfer process can proceed normally, but the transferred light emitting device ED itself can have a defect. Therefore, considering the defects (including non-transfer defects) that occur during the transfer process of the light emitting devices EDs, the main light emitting device and the redundancy light emitting device, which are light emitting devices of the same type (e.g., light emitting devices that emit light of the same color), can be transferred to one sub-pixel SP. A lighting test can be performed on the main light emitting device and the redundancy light emitting device of the same type, and it is possible to utilize only one of the main light emitting device and the redundancy light emitting device that is finally determined to be normal.

For example, the first main light emitting device EDa_M and the first redundancy light emitting device EDa_R can be transferred together to one first sub-pixel SPa, and the first main light emitting device EDa_M and the first redundancy light emitting device EDa_R can be inspected for defects. If, as a result of the inspection, both the first main light emitting device EDa_M and the first redundancy light emitting device EDa_R are determined to be normal, only the first main light emitting device EDa_M can be used, and the first redundancy light emitting device EDa_R can be not used. If, as a result of the inspection, only the first redundancy light emitting device EDa_R among the first main light emitting device EDa_M and the first redundancy light emitting device EDa_R is normal, the first main light emitting device EDa_M is not used, and only the first redundancy light emitting device EDa_R can be used. Accordingly, even if the same first main light emitting device EDa_M and the first redundancy light emitting device EDa_R are transferred to one first sub-pixel SPa, only one of the first main light emitting device EDa_M and the first redundancy light emitting device EDa_R can be used finally.

Accordingly, among the main light emitting device and the redundancy light emitting device arranged in one sub-pixel SP, the redundancy light emitting device can be a spare light emitting device transferred in preparation for a failure of the main light emitting device. In the event of a failure of the main light emitting device, the redundancy light emitting device can be used as a replacement. Therefore, by transferring the main light emitting device and the redundancy light emitting device together to one sub-pixel SP, it is possible to minimize or reduce the deterioration of display quality due to a defect in one of the main light emitting device and the redundancy light emitting device.

In the embodiments of the present disclosure, the first main sub-pixel SPa_M and the first redundancy sub-pixel SPa_R can also be referred to as a 1-1 sub-pixel and a 1-2 sub-pixel, respectively, the second main sub-pixel SPb_M and the second redundancy sub-pixel SPb_R can also be referred to as a 2-1 sub-pixel and a 2-2 sub-pixel, and the third main sub-pixel SPc_M and the third redundancy sub-pixel SPc_R can also be referred to as a 3-1 sub-pixel and a 3-2 sub-pixel, respectively.

In the embodiments of the present disclosure, the first main light emitting device EDa_M and the first redundancy light emitting device EDa_R can also be referred to as a 1-1 light emitting device and a 1-2 light emitting device, the second main light emitting device EDb_M and the second redundancy light emitting device EDb_R can also be referred to as a 2-1 light emitting device and a 2-2 light emitting device, and the third main light emitting device EDc_M and the third redundancy light emitting device EDc_R can also be referred to as a 3-1 light emitting device and a 3-2 light emitting device.

The display panel 110 according to the embodiments of the present disclosure can further include a plurality of communication lines NL. The plurality of communication lines NL can be arranged so as not to overlap with the metal layer in a vertical direction. For example, a plurality of communication lines NL can be arranged between a first row line RL(1) and a second row line RL(2.

For example, the plurality of communication lines NL can be wires for short-range communication such as NFC (Near Field Communication) and Bluetooth. The plurality of communication lines NL can serve as signal transmission wires and/or antennas.

Referring to FIG. 8, each of the first row line RL(1) and the second row line RL(2) can be arranged above a plurality of light emitting devices, and can be arranged in a bar shape overlapping with all of the plurality of light emitting devices.

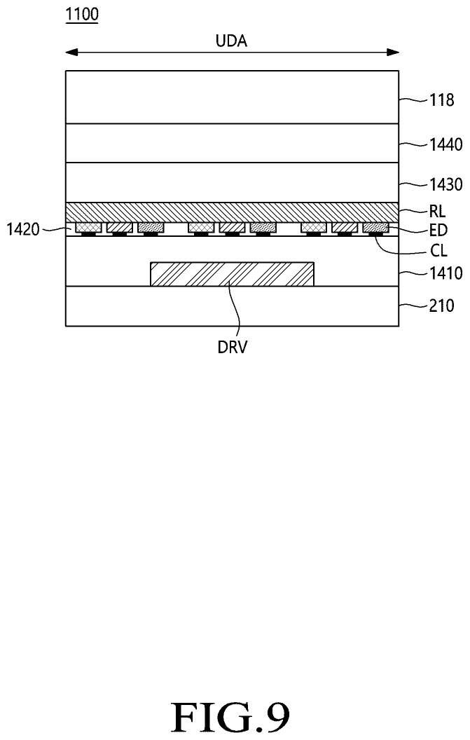

FIG. 9 is a cross-sectional view of a display panel 110 according to embodiments of the present disclosure. However, FIG. 9 is a cross-sectional view of a portion of a unit driving area UDA in which one driver DRV is arranged.

Referring to FIG. 9, a display panel 110 can include a substrate 210, a driver DRV on the substrate 210, a layer stack 1410 on the driver DRV, a plurality of light emitting devices ED disposed on the layer stack 1410, an optical layer 1420 disposed on the layer stack 1410 and between the plurality of light emitting devices ED, an overcoat layer 1430 disposed on the plurality of light emitting devices ED and the optical layer 1420, an adhesive layer 1440 disposed on the overcoat layer 1430, and a cover member 118 disposed on the adhesive layer 1440.

A plurality of column lines CL can be arranged on a layer stack 1410. Each of the plurality of column lines CL can be arranged between the layer stack 1410 and a light emitting device ED. A plurality of row lines RL can be arranged on a plurality of light emitting devices ED and an optical layer 1420.

A display panel 110 can include a substrate 210 including a display area DA, a plurality of light emitting devices ED arranged in the display area DA, a plurality of column lines CL electrically connected to first electrodes Ecl of each of the plurality of light emitting devices ED, a plurality of row lines RL electrically connected to second electrodes Erl of each of the plurality of light emitting devices ED, and a plurality of drivers DRV configured to drive the plurality of light emitting devices ED, the plurality of column lines CL, and the plurality of row lines RL.

A plurality of drivers DRV can be arranged in the display area DA, and can be positioned closer to the substrate 210 than the plurality of light emitting devices ED.

The layer stack 1410 can include a plurality of insulating layers. The plurality of insulating layers can include a plurality of organic layers. At least one of the plurality of organic layers can be arranged on a side of the driver DRV. For example, two or more organic layers can be arranged on a side of the driver DRV.

The layer stack 1410 can further include at least one metal layer connecting the driver DRV and the column line CL, and at least one metal layer connecting the driver DRV and the row line RL.

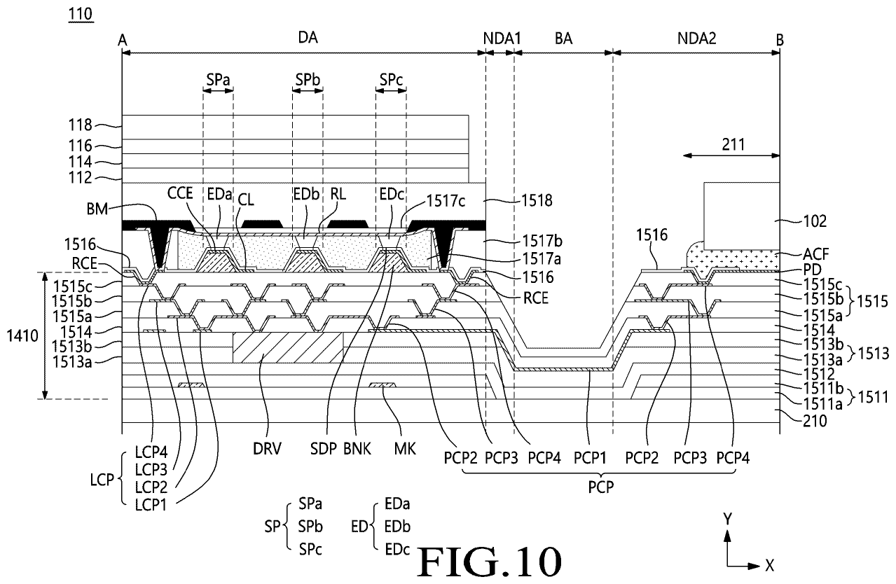

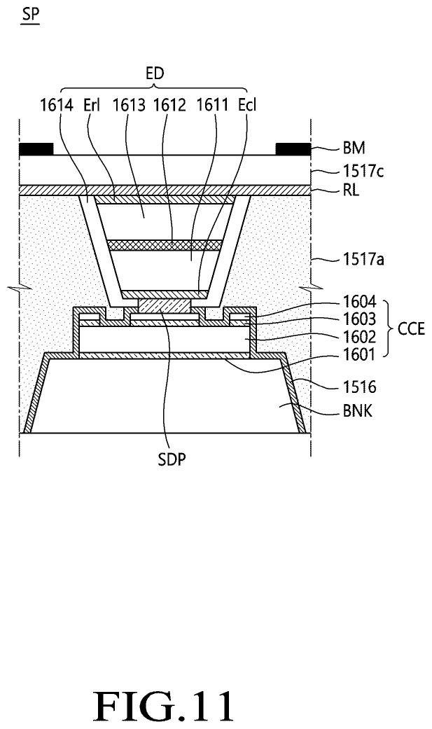

FIG. 10 is a detailed cross-sectional view of a display panel 110 according to embodiments of the present disclosure taken along the A-B cutting line of FIG. 6, and FIG. 11 is an enlarged cross-sectional view of a first sub-pixel SP of a display panel 110 according to embodiments of the present disclosure. However, FIG. 10 is a cross-sectional view of a display area DA, a first non-display area NDA, a bending area BA, and a second non-display area NDA.

Meanwhile, for convenience of illustration, the A-B cutting line in FIG. 6 is illustrated as not overlapping with a signal line SL and a link line LL, but the A-B cutting line in FIG. 6 is intended to indicate the same position as the adjacent signal line SL and the link line LL.

Referring to FIGS. 10 and 11, a buffer layer 1511 can be disposed on the substrate 210. The buffer layer 1511 can include a first buffer layer 1511a and a second buffer layer 1511b. The first buffer layer 1511a and the second buffer layer 1511b can be arranged in the display area DA, the first non-display area NDA1, and the second non-display area NDA, and may not be arranged in the entirety or part of the bending area BA.

The first buffer layer 1511a and the second buffer layer 1511b can reduce the penetration of moisture or impurities through the substrate 210. The first buffer layer 1511a and the second buffer layer 1511b can be made of an inorganic insulating material. For example, the first buffer layer 1511a and the second buffer layer 1511b can be composed of a single layer or multiple layers of silicon oxide (SiOx) or silicon nitride (SiNx).

For example, a portion of the first buffer layer 1511a and the second buffer layer 1511b on the bending area BA can be removed. The upper surface of the substrate 210 located on the bending area BA can be exposed by the area (e.g., opening) where the first buffer layer 1511a and the second buffer layer 1511b are removed.

By removing the first buffer layer 1511a and the second buffer layer 1511b from the bending area BA, it is possible to minimize or reduce an occurrence of cracks in the first buffer layer 1511a and the second buffer layer 1511b that can occur during bending.

A plurality of alignment keys MK can be arranged between the first buffer layer 1511a and the second buffer layer 1511b. The plurality of alignment keys MK can be configured to identify the position of the driver DRV during the manufacturing process of the display panel 110. For example, the plurality of alignment keys MK can be configured to align the position of the driver DRV transferred on the adhesive layer 1512. In another example, the plurality of alignment keys MK can be omitted.

An adhesive layer 1512 can be disposed on the second buffer layer 1511b. The adhesive layer 1512 can be disposed in the display area DA, the first non-display area NDA1, the bending area BA, and the second non-display area NDA2. For another example, at least a portion of the adhesive layer 1512 can be removed in the non-display area NDA including the bending area BA. For example, the adhesive layer 1512 can be made of any one of an adhesive polymer, an epoxy resin, a UV-curable resin, a polyimide series, an acrylate series, a urethane series, and a polydimethylsiloxane (PDMS).

A driver DRV can be disposed on the adhesive layer 1512 in the display area DA. If the driver DRV is implemented as a driving chip (e.g., driver integrated circuit), the driving driver can be mounted on the adhesive layer 1512 by a transfer process.

The display panel 110 can further include a side protection layer 1513 disposed on the side of the plurality of drivers DRV, and an upper protection layer 1514 disposed on the plurality of drivers DRV and the side protection layer 1513. For example, the side protection layer 1513 can include at least one of a first protection layer 1513a and a second protection layer 1513b disposed on the side of the plurality of drivers DRV, and in some cases, can further include at least one additional protection layer. The first protection layer 1513a and the second protection layer 1513b can be disposed on the adhesive layer 1512. The first protection layer 1513a and the second protection layer 1513b can be arranged to surround the side surface of the driver DRV. For example, the second protection layer 1513b can be arranged to cover at least a portion of the upper surface of the driver DRV. For example, at least one of the first protection layer 1513a and the second protection layer 1513b arranged on the bending area BA can be omitted. For example, the first protection layer 1513a can be arranged entirely on the display area DA and the non-display area NDA, and the second protection layer 1513b can be partially arranged on the display area DA, the first non-display area NDA1, and the second non-display area NDA2. For example, at least a portion of the second protection layer 1513b can be removed in all or part of the bending area BA.

For example, the side protection layer 1513 including at least one of the first protection layer 1513a and the second protection layer 1513b can be composed of an organic insulating material (i.e., organic layer), but the embodiments of the present disclosure are not limited thereto. For example, the first protection layer 1513a and the second protection layer 1513b can be composed of a photo resist, a polyimide (PI), or a photo acryl-based material. For example, the first protection layer 1513a and the second protection layer 1513b can be an overcoating layer or an insulating layer.

The display panel 110 can further include a plurality of insulating layers 1515 disposed on the upper protection layer 1514. For example, the plurality of insulating layers 1515 can include a first insulating layer 1515a, a second insulating layer 1515b, and a third insulating layer 1515c.

In the display area DA, a plurality of line connection patterns LCP can be arranged on the second protection layer 1513b. The plurality of line connection patterns LCP can be wiring for electrically connecting the driver DRV to other components. For example, the driver DRV can be electrically connected to a plurality of column lines CL, a plurality of row lines RL, and a plurality of row connection electrodes RCE through the plurality of line connection patterns LCP.

For example, the plurality of line connection patterns LCP can include a first line connection pattern LCP1, a second line connection pattern LCP2, a third line connection pattern LCP3, and a fourth line connection pattern LCP4. For example, the first line connection pattern LCP1, the second line connection pattern LCP2, the third line connection pattern LCP3, and the fourth line connection pattern LCP4 can be arranged in different metal layers.

For example, a plurality of first line connection patterns LCP1 can be arranged on the second protection layer 1513b. The plurality of first line connection patterns LCP1 can be electrically connected to the driver DRV. The plurality of first line connection patterns LCP1 can transmit the voltage output from the driver DRV to the column line CL or the row line RL.

The display panel 110 can further include a side protection layer 1513 including at least one of the first protection layer 1513a and the second protection layer 1513b, and an upper protection layer 1514 arranged on the plurality of drivers DRV. For example, the upper protection layer 1514 can include a third protection layer 1514, and in some cases, can further include at least one additional protection layer. The third protection layer 1514 can be disposed on the second protection layer 1513b and the plurality of first line connection patterns LCP1. The third protection layer 1514 can be disposed entirely in the display area DA and the non-display area NDA. In the bending area BA, the third protection layer 1514 can cover or enclose the side surface of the second protection layer 1513b and the upper surface of the first protection layer 1513a.

For example, the third protection layer 1514 can be composed of an organic insulating material. For example, the third protection layer 1514 can be composed of a photo resist, a polyimide (PI), or a photo acryl-based material. For example, the first protection layer 1513a, the second protection layer 1513b, and the third protection layer 1514 can be composed of the same insulating material, or at least one of the first protection layer 1513a, the second protection layer 1513b, and the third protection layer 1514 can be composed of a different insulating material from the rest.

A plurality of second line connection patterns LCP2 can be arranged on the third protection layer 1514. The plurality of second line connection patterns LCP2 can be electrically connected or directly connected to the driver DRV. For example, some of the second line connection patterns LCP2 can be directly or indirectly connected to the driver DRV through contact holes of the third protection layer 1514. Other parts of the second line connection patterns LCP2 can be electrically connected to the first line connection pattern LCP1 through contact holes of the third protection layer 1514. However, the embodiments of the present disclosure are not limited thereto. The voltage output from the driver DRV can be transmitted to the column line CL or the row line RL through the plurality of second line connection patterns LCP2 and other connection patterns.

A first insulating layer 1515a can be disposed on the plurality of second line connection patterns LCP2. The first insulating layer 1515a can be disposed entirely over the display area DA and the non-display area NDA. The first insulating layer 1515a can be composed of an organic insulating material. For example, the first insulating layer 1515a can be composed of a photo resist, a polyimide (PI), or a photo acryl-based material.

A plurality of third line connection patterns LCP3 can be disposed on the first insulating layer 1515a. The plurality of third line connection patterns LCP3 can be electrically connected to the plurality of second line connection patterns LCP2. For example, the third line connection pattern LCP3 can be electrically connected to the second line connection pattern LCP2 through a contact hole of the first insulating layer 1515a.

A second insulating layer 1515b can be disposed on a plurality of third line connection patterns LCP3. The second insulating layer 1515b can be disposed in the display area DA, the first non-display area NDA1, and the second non-display area NDA2, and may not be disposed in the entirety or part of the bending area BA, but the embodiments of the present disclosure are not limited thereto. For example, the second insulating layer 1515b can be removed from the entirety or part of the bending area BA. The second insulating layer 1515b can be composed of an organic insulating material. For example, the second insulating layer 1515b can be composed of a photo resist, a polyimide (PI), or a photo acryl-based material.

A plurality of fourth line connection patterns LCP4 can be arranged on the second insulating layer 1515b. The plurality of fourth line connection patterns LCP4 can be electrically connected to a plurality of third line connection patterns LCP3. For example, the fourth line connection patterns LCP4 can be electrically connected to the third line connection patterns LCP3 through a contact hole of the second insulating layer 1515b.

In the non-display area NDA, a plurality of pad connection patterns PCP can be arranged on the second protection layer 1513b. A plurality of pad connection patterns PCPs can be wiring for transmitting a signal transmitted from a flexible printed circuit 102 to a pad section 211 to a driver DRV of a display area DA. For example, a plurality of pad connection patterns PCP can be electrically connected to a plurality of pads PDs and can receive signals from the flexible printed circuit 102 through the plurality of pads PDs. The flexible printed circuit 102 can be connected to a printed circuit board 104 (see FIGS. 1 and 2).

For example, a plurality of pad connection patterns PCP can extend from the pad section 211 toward the display area DA and transmit signals to the wiring of the display area DA. In this case, a plurality of pad connection patterns PCP can function as link line LL (see FIG. 6). The plurality of pad connection patterns PCP can include a first pad connection pattern PCP1, a second pad connection pattern PCP2, a third pad connection pattern PCP3, and a fourth pad connection pattern PCP4.

The plurality of first pad connection patterns PCP1 can be arranged on the second protection layer 1513b. Each of the plurality of first pad connection patterns PCP1 can be arranged across the second non-display area NDA2, the bending area BA, and the first non-display area NDA1. Each of the plurality of first pad connection patterns PCP1 can include a first portion arranged in the bending area BA, a second portion extending from the first portion to the first non-display area NDA1, and a third portion extending from the first portion to the second non-display area NDA2. Each of the plurality of first pad connection patterns PCP1 can extend from the first non-display area NDA1 to a portion of the display area DA. The plurality of first pad connection patterns PCP1 can transmit a signal transmitted from the flexible printed circuit 102 to the pad section 211 to the driver DRV of the display area DA.

Each of the plurality of first pad connection patterns PCP1 can be electrically connected to the pad PD of the pad section 211 through connection patterns arranged in the second non-display area NDA2. Here, the connection patterns electrically connecting each of the plurality of first pad connection patterns PCP1 to the pad PD can include at least one of the second pad connection pattern PCP2, the third pad connection pattern PCP3, and the fourth pad connection pattern PCP4 arranged in the second non-display area NDA2.

Each of the plurality of first pad connection patterns PCP1 can be electrically connected to the driver DRV through connection patterns arranged in the display area DA. Here, the connection patterns electrically connecting each of the plurality of first pad connection patterns PCP1 to the driver DRV can include at least one of the second pad connection pattern PCP2, the third pad connection pattern PCP3, and the fourth pad connection pattern PCP4 arranged in the display area DA.

The plurality of second pad connection patterns PCP2 can be arranged on the third protection layer 1514. The plurality of second pad connection patterns PCP2 can be arranged in the second non-display area NDA2. The second pad connection pattern PCP2 can be electrically connected to the first pad connection pattern PCP1 through a contact hole of the third protection layer 1514. Therefore, the signal supplied from the flexible printed circuit 102 can be transmitted to the first pad connection pattern PCP1 through the second pad connection pattern PCP.

The third pad connection pattern PCP3 can be arranged on the first insulating layer 1515a. The third pad connection pattern PCP3 can be arranged in the second non-display area NDA2. The third pad connection pattern PCP3 can be electrically connected to the second pad connection pattern PCP2 through a contact hole of the first insulating layer 1515a. Therefore, the signal supplied from the flexible printed circuit 102 can be transmitted to the second pad connection pattern PCP2 through the third pad connection pattern PCP3, and the signal transmitted to the second pad connection pattern PCP2 can be transmitted again to the first pad connection pattern PCP1.

The fourth pad connection pattern PCP4 can be arranged on the second insulating layer 1515b. The fourth pad connection patternPCP4) can be arranged in the second non-display area NDA2. The fourth pad connection pattern PCP4 can be electrically connected to the third pad connection pattern PCP3 through a contact hole of the second insulating layer 1515b. The pad PD of the pad section 211 can be electrically connected to the fourth pad connection pattern PCP4 through a contact hole of the third insulating layer 1515c.

A signal supplied from a flexible printed circuit 102 is input to a pad PD of a pad section 211, and a signal input to the pad PD is transmitted to a third pad connection pattern PCP3 through a fourth pad connection pattern PCP4, and a signal transmitted to the third pad connection pattern PCP3 can be transmitted again to a first pad connection pattern PCP1 through a second pad connection pattern PCP2. A signal transmitted to the first pad connection pattern PCP1 can be transmitted to a driver DRV through connection patterns arranged in a display area DA.

The plurality of line connection patterns LCP and a plurality of pad connection patterns PCP can be arranged in various metal layers. The plurality of line connection patterns LCP and the plurality of pad connection patterns PCP can be formed of any one of a conductive material having excellent ductility or various conductive materials used in a display area DA.

For example, a metal pattern such as a first pad connection pattern PCP1 at least partially disposed in the bending area BA can be composed of a conductive material having excellent ductility, such as gold (Au), silver (Ag), or aluminum (Al). For another example, the plurality of line connection patterns LCP and the plurality of pad connection patterns PCP can be composed of molybdenum (Mo), chromium (Cr), titanium (Ti), nickel (Ni), neodymium (Nd), copper (Cu), and an alloy of silver (Ag) and magnesium (Mg), or an alloy thereof.

A third insulating layer 1515c can be disposed on the plurality of line connection patterns LCP and the plurality of pad connection patterns PCP. The third insulating layer 1515c is disposed in the display area DA, the first non-display area NDA1, and the second non-display area NDA2, and can be disposed in all or part of the bending area BA. In the bending area BA, a part of the third insulating layer 1515c can be removed. The third insulating layer 1515c can be composed of an organic insulating material. For example, the third insulating layer 1515c can be composed of a photo resist, a polyimide (PI), or a photo acryl-based material.

A plurality of banks BNK can be disposed on the third insulating layer 1515c in the display area DA. The plurality of banks BNKs can be arranged to overlap with at least a portion of each of the plurality of sub-pixels SPa, SPb and SPc. For example, the first sub-pixel SPa can include a first light emitting device EDa that emits a first color light, the second sub-pixel SPb can include a second light emitting device EDb that emits a second color light, and the third sub-pixel SPc can include a third light emitting device EDc that emits a third color light.

As an example, one light emitting device ED can be arranged on top of each of the plurality of banks BNKs. As another example, two or more light emitting devices ED can be arranged on top of each of the plurality of banks BNK. The two or more light emitting devices EDs arranged on top of each of the plurality of banks BNK can be light emitting devices of the same type. For example, the light emitting devices of the same type can be light emitting devices that emit the same color light. For example, the two or more light emitting devices ED arranged on top of each of the plurality of banks BNK can include a main light emitting device and a redundancy light emitting device.

In the display area DA, a plurality of row connection electrodes RCE can be arranged on the third insulating layer 1515c. The plurality of row connection electrodes RCE can transfer a low-potential voltage VSS output from the driver DRV to the row line RL.

In the display area DA, a plurality of column lines CL can be arranged on the third insulating layer 1515c. The plurality of column lines CL can be arranged in an area between the plurality of banks BNK. For example, the plurality of column lines CL can be arranged adjacent to one of the plurality of banks BNK.

Each of the plurality of column lines CL can include a wiring portion and a column connection electrode CCE protruding from the wiring portion. The wiring portion and the column connection electrode CCE included in each of the plurality of column lines CL can be formed integrally or can be different metals that are electrically connected.

For example, each of the plurality of column lines CL can include a column connection electrode CCE that is a portion protruding above an adjacent bank BNK among the plurality of banks BNK. The column connection electrode CCE of each of the plurality of column lines CL can be arranged to extend along the side and upper surface of the bank BNK. The column connection electrode CCE can be an electrode electrically connected to each of the plurality of column lines CL or can be a portion protruding from each of the plurality of column lines CL.

The column connection electrode CCE of the column line CL can be composed of one conductive layer or multiple conductive layers. For example, a column connection electrode CCE electrically connected to a column line CL or protruding from the column line CL can include a first conductive layer 1601, a second conductive layer 1602, a third conductive layer 1603, and a fourth conductive layer 1604.

The first conductive layer 1601 can be disposed on a bank BNK. The second conductive layer 1602 can be disposed on the first conductive layer 1601. The third conductive layer 1603 can be disposed on the second conductive layer 1602, and the fourth conductive layer 1604 can be disposed on the third conductive layer 1603. For example, each of the first conductive layer 1601, the second conductive layer 1602, the third conductive layer 1603, and the fourth conductive layer 1604 can be composed of titanium (Ti), molybdenum (Mo), aluminum (Al), or titanium (Ti) and indium tin oxide (ITO).

Among the plurality of conductive layers constituting the column connection electrode CCE, some conductive layers having good reflection efficiency can be configured as an alignment key and/or a reflector for aligning the light emitting devices ED. For example, among the plurality of conductive layers constituting the column connection electrode CCE, the second conductive layer 1602 can include a reflective material. For example, the second conductive layer 1602 can include aluminum (Al). Accordingly, the second conductive layer 1602 can be configured as a reflector. In addition, due to the high reflection efficiency of the second conductive layer 1602, it can be easily identified in the manufacturing process, and thus the position or transfer position of the light emitting device ED can be aligned based on the second conductive layer 1602.

For example, in order to configure the second conductive layer 1602 as a reflector, the third conductive layer 1603 and the fourth conductive layer 1604 disposed on the second conductive layer 1602 can be partially removed or etched. For example, a portion of the third conductive layer 1603 and the fourth conductive layer 1604 disposed on the bank BNK can be removed or etched to expose the upper surface of the second conductive layer 1602. For example, the openings of the third conductive layer 1603 and the fourth conductive layer 1604 can overlap with a portion of the upper surface of the second conductive layer 1602. For example, in the third conductive layer 1603 and the fourth conductive layer 1604, the central portion and the edge portion where a solder pattern SDP is arranged can remain, and the remaining portions excluding this portion (e.g., the central portion, the edge portion) can be removed. For example, the edge portion of each of the third conductive layer 1603 made of titanium (Ti) and the fourth conductive layer 1604 made of indium tin oxide (ITO) may not be etched. Accordingly, it is possible to prevent or reduce other conductive layers of the column connection electrode CCE of the column line CL from being corroded by the TMAH (Tetra Methyl Ammonium Hydroxide) solution used in the mask process of the column connection electrode CCE.

The first conductive layer 1601 and the third conductive layer 1603 can include titanium (Ti) or molybdenum (Mo). The second conductive layer 1602 can include aluminum (Al). The fourth conductive layer 1604 can include a transparent conductive oxide layer such as indium tin oxide (ITO) or indium zinc oxide (IZO) that has good adhesion to the solder pattern SDP and corrosion resistance and acid resistance.

The first conductive layer 1601, the second conductive layer 1602, the third conductive layer 1603, and the fourth conductive layer 1604 can be sequentially deposited and then patterned by performing a photolithography process and an etching process.

Two or more of the column connection electrode CCE, the column line CL, the row connection electrode RCE, and the pad PD can be arranged on the same layer. The column connection electrode CCE, the column line CL, the row connection electrode RCE, and the pad PD can be composed of a single layer or multiple layers of a conductive material. For example, two or more of the column connection electrode CCE, the column line CL, the row connection electrode RCE, and the pad PD can be composed of a multiple layer of indium tin oxide (ITO)/titanium (Ti)/aluminum (Al)/titanium (Ti).

A solder pattern SDP can be disposed on the column connection electrode CCE in each of a plurality of sub-pixels. The solder pattern SDP can bond the light emitting device ED to the column connection electrode CCE. The column connection electrode CCE and the light emitting device ED can be electrically connected through eutectic bonding using the solder pattern SDP. For example, if the solder pattern SDP is composed of indium (In) and the first electrode Ecl of the light emitting device ED is composed of gold (Au), the solder pattern SDP and the first electrode Ecl of the light emitting device ED can be bonded by applying heat and pressure in a transfer process of the light emitting device ED. Through eutectic bonding, the light emitting device ED can be bonded to the solder pattern SDP and the column connection electrode CCE without a separate adhesive. For example, the solder pattern SDP can be composed of indium (In), tin (Sn), or an alloy thereof. For example, the solder pattern SDP can be a bonding pad.

The passivation layer 1516 can be disposed on a plurality of column lines CL, a plurality of column connection electrodes CCE, a plurality of row connection electrodes RCE, and a third insulating layer 1515c.

For example, the passivation layer 1516 can be disposed on a display area DA, a first non-display area NDA1, and a second non-display area NDA2. In the entirety or a portion of the bending area BA, at least a portion of the passivation layer 1516 covering the plurality of pads PD can be removed. A portion of the passivation layer 1516 covering the plurality of pads PD in the second non-display area NDA2 can be removed. In addition, as illustrated in FIG. 11, the passivation layer 1516 can be removed from the area where the solder pattern SDP is arranged.

Since the passivation layer 1516 is arranged to cover the remaining area except for the bending area BA, the plurality of pads PD, and the area where the solder pattern SDP is arranged, the penetration of moisture or impurities into the light emitting device ED can be reduced. For example, the passivation layer 1516 can be composed of a single layer or multiple layers of silicon oxide (SiOx) or silicon nitride (SiNx), but the embodiments of the present disclosure are not limited thereto. For example, the passivation layer 1516 can be a protection layer or an insulating layer, but the embodiments of the present disclosure are not limited thereto. For example, as illustrated in FIG. 10, the passivation layer 1516 can include a hole through which the solder pattern SDP is exposed. For example, the hole of the passivation layer 1516 can overlap with the solder pattern SDP.

The light emitting device ED can be arranged on the solder pattern SDP in each of a plurality of sub-pixels SP. The light emitting device ED can be formed on a silicon wafer by a method such as Metal Organic Chemical Vapor Deposition (MOCVD), Chemical Vapor Deposition (CVD), Plasma-Enhanced Chemical Vapor Deposition (PDCVD), Molecular Beam Epitaxy (MBE), Hydride Vapor Phase Epitaxy (HVPD), or Sputtering.

The light emitting device ED can include a first electrode Ecl, a first semiconductor layer 1611, an active layer 1612, a second semiconductor layer 1613, a second electrode Erl, and an encapsulation film 1614. In some cases, the encapsulation film 1614 may not be included in the light emitting device ED.

The first semiconductor layer 1611 can be disposed on the solder pattern SDP. The second semiconductor layer 1613 can be disposed on the first semiconductor layer 1611.

For example, one of the first semiconductor layer 1611 and the second semiconductor layer 1613 can be implemented as a compound semiconductor of group III-V, group II-VI, and can be doped with an impurity (or dopant). For example, one of the first semiconductor layer 1611 and the second semiconductor layer 1613 can be a semiconductor layer doped with an n-type impurity, and the other can be a semiconductor layer doped with a p-type impurity. For example, at least one of the first semiconductor layer 1611 and the second semiconductor layer 1613 can be a layer doped with an n-type or p-type impurity in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs), but the embodiments of the present disclosure are not limited thereto. For example, the n-type impurity can be silicon (Si), germanium (Ge), selenium (Se), carbon (C), tellurium TE, or tin (Sn), but the embodiments of the present disclosure are not limited thereto. For example, the p-type impurity can be magnesium (Mg), zinc (Zn), calcium (Ca), strontium (Sr), barium (Ba), or beryllium (Be).

For example, the first semiconductor layer 1611 and the second semiconductor layer 1613 can be a nitride semiconductor including an n-type impurity and a nitride semiconductor including a p-type impurity, respectively. For example, the first semiconductor layer 1611 can be a nitride semiconductor containing a p-type impurity, and the second semiconductor layer 1613 can be a nitride semiconductor containing an n-type impurity.

The active layer 1612 can be arranged between the first semiconductor layer 1611 and the second semiconductor layer 1613. The active layer 1612 can receive holes and electrons from the first semiconductor layer 1611 and the second semiconductor layer1613) to emit light. For example, the active layer 1612 can be configured as one of a single well structure, a multi-well structure, a single quantum well structure, a multi-quantum well (MQW) structure, a quantum dot structure, and a quantum wire structure. For example, the active layer 1612 can be configured as indium gallium nitride (InGaN) or gallium nitride (GaN). For another example, the active layer 1612 can include a multi-quantum well (MQW) structure having a well layer and a barrier layer having a higher band gap than the well layer. For example, the active layer 1612 can be formed of InGaN as a well layer and an AlGaN layer as a barrier layer.

The first electrode Ecl of the light emitting device ED can be arranged between the first semiconductor layer 1611 and the solder pattern SDP. For example, the first electrode Ecl of the light emitting device ED can electrically connect the first semiconductor layer 1611 and the column connection electrode CCE. The column line voltage (e.g., the anode voltage) output from the driver DRV can be applied to the first semiconductor layer 1611 through the column line CL, the column connection electrode CCE, and the first electrode Ecl. For example, the first electrode Ecl can be composed of a conductive material capable of eutectic bonding with the solder pattern SDP. For example, the first electrode Ecl of the light emitting device ED can be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof.

The second electrode Erl of the light emitting device ED can be disposed on the second semiconductor layer 1613. For example, the second electrode Erl of the light emitting device ED can electrically connect the second semiconductor layer 1613 and the row line RL. A row line voltage (e.g., referred to as a low-potential voltage VSS as a cathode voltage) output from the driver DRV can be applied to the second semiconductor layer 1613 through the row connection electrode RCE, the row line RL, and the second electrode Erl. The second electrode Erl of the light emitting device ED can be made of a transparent conductive material so that light emitted from the light emitting device ED can be directed to the upper portion of the light emitting device ED, but the embodiments of the present disclosure are not limited thereto. For example, the second electrode Erl can be made of a material such as indium tin oxide (ITO), indium zinc oxide (IZO), or indium gallium zinc oxide (IGZO).

The encapsulation film 1614 can be disposed on at least a portion of the first semiconductor layer 1611, the active layer 1612, the second semiconductor layer 1613, the first electrode Ecl, and the second electrode Erl. For example, the encapsulation film 1614 can surround at least a portion of the first semiconductor layer 1611, the active layer 1612, the second semiconductor layer 1613, the first electrode Ecl, and the second electrode Erl.

For example, the encapsulation film 1614 can protect the first semiconductor layer 1611, the active layer 1612, and the second semiconductor layer 1613. For example, the encapsulation film 1614 can be disposed on a side surface of the first semiconductor layer 1611, a side surface of the active layer 1612, and a side surface of the second semiconductor layer 161.

For example, the encapsulation film 1614 can be disposed on at least a portion of the first electrode Ecl and the second electrode Erl of the light emitting device ED. For example, the encapsulation film 1614 can be disposed on an edge portion (or one side) of the first electrode Ecl of the light emitting device ED and an edge portion (or one side) of the second electrode Erl of the light emitting device ED. At least a portion of the first electrode Ecl can be exposed from the encapsulation film 1614 so that the first electrode Ecl can be connected to the solder pattern SDP. For example, at least a portion of the second electrode Erl can be exposed from the encapsulation film 1614 so that the second electrode Erl can be connected to the row line RL. For example, the encapsulation film 1614 can be made of an insulating material such as silicon nitride (SiNx) or silicon oxide (SiOx).

For another example, the encapsulation film 1614 can have a structure in which a reflective material is dispersed in a resin layer, but the embodiments of the present disclosure are not limited thereto. For example, the encapsulation film 1614 can be manufactured as a reflector of various structures, but the embodiments of the present disclosure are not limited thereto. Light emitted from the active layer 1612 can be reflected upward by the encapsulation film 1614, thereby improving light extraction efficiency. For example, the encapsulation film 1614 can be a reflective layer.

The light emitting device ED can have a vertical structure. Alternatively, the light emitting device ED can have a lateral structure or a flip chip structure.

The structure of the light emitting device ED illustrated in FIG. 11 can be substantially equally applied to all of the first light emitting device EDa, the second light emitting device EDb, and the third light emitting device EDc. A first optical layer 1517a can be arranged to surround a plurality of light emitting devices ED in the display area DA. For example, the first optical layer 1517a can be arranged to cover a plurality of light emitting devices ED and the bank BNK in the area of a plurality of sub-pixels SP. For example, the first optical layer 1517a can cover a bank BNK, a portion of the passivation layer 1516, and a region between the plurality of light emitting devices ED. The first optical layer 1517a can be arranged or covered between a plurality of light emitting devices ED included in one pixel and between a plurality of banks BNK. For example, the first optical layer 1517a can be arranged to surround the side of the light emitting devices ED and the banks BNK between the passivation layer 1516 and the row line RL. For example, the first optical layer 1517a can be a diffusion layer or a sidewall diffusion layer.

The first optical layer 1517a can include an organic insulating material having fine particles dispersed therein. For example, the first optical layer 1517a can be composed of siloxane having fine metal particles, such as titanium dioxide (TiO2) particles, dispersed therein. Light from a plurality of light emitting devices ED can be scattered by the fine particles dispersed in the first optical layer 1517a and emitted to the outside of the display device 100. Accordingly, the first optical layer 1517a can improve the extraction efficiency of light emitted from the plurality of light emitting devices ED.

For example, the first optical layer 1517a can be arranged on each of a plurality of pixels, or can be arranged together on some pixels arranged in the same row. For example, the first optical layer 1517a can be arranged on each of a plurality of pixels, or the plurality of pixels can share one first optical layer 1517a. For another example, each of the plurality of sub-pixels can separately include a first optical layer 1517a.

In the display area DA, a second optical layer 1517b can be arranged on the passivation layer 1516. For example, the second optical layer 1517b can be arranged to surround the first optical layer 1517a. For example, the second optical layer 1517b can be in contact with a side surface of the first optical layer 1517a. For example, the second optical layer 1517b can be arranged in an area between the plurality of pixels. For example, the second optical layer 1517b can be a diffusion layer, a diffusion layer window, or a window diffusion layer.

The second optical layer 1517b can be composed of an organic insulating material. The second optical layer 1517b can be composed of the same material as the first optical layer 1517a. For example, the first optical layer 1517a can include fine particles, and the second optical layer 1517b may not include fine particles. For example, the second optical layer 1517b can be composed of siloxane.

For example, the thickness of the first optical layer 1517a can be smaller than the thickness of the second optical layer 1517b. Accordingly, when viewed from a planar view, the area where the first optical layer 1517a is disposed can include a concave portion that is sunken inwardly from the upper surface of the second optical layer 1517b.

The row line RL can be disposed on the first optical layer 1517a and the second optical layer 1517b. For example, the row line RL can be electrically connected to a plurality of row connection electrodes RCE through contact holes of the second optical layer 1517b. For example, the row line RL can be disposed on a plurality of light emitting devices ED. For example, the row line RL can include a transparent conductive oxide such as indium tin oxide (ITO) or indium zinc oxide (IZO). For example, the row line RL can be arranged to be in contact with the second electrode Erl of the light emitting device ED. For example, the row line RL can overlap with the first optical layer 1517a. For example, the row line RL can cover a plane on the outside of the first optical layer 1517a.

The row line RL can extend continuously in the first direction (X) of the substrate 210. Accordingly, the row line RL can be commonly connected to a plurality of pixels arranged in the first direction (X) of the substrate 210. For example, the row line RL can be commonly connected to a plurality of pixels.

The row line RL can be continuously extended on the first optical layer 1517a, the second optical layer 1517b, and the light emitting device ED. The area where the first optical layer 1517a is disposed can include a concave portion that is sunken inwardly from the upper surface of the second optical layer 1517b. Accordingly, the first part of the row line RL disposed on the first optical layer 1517a can be disposed along the concave portion, and thus can be disposed at a lower position than the second part of the row line RL disposed on the second optical layer 1517b.

A third optical layer 1517c can be disposed on the row line RL. The third optical layer 1517c can be disposed so as to overlap with a plurality of light emitting devices ED and the first optical layer 1517a. Since the third optical layer 1517c is arranged on the row line RL and the plurality of light emitting devices ED, it is possible to improve a mura that can occur in some of the plurality of light emitting devices ED. For example, when transferring a plurality of light emitting devices ED onto the substrate 210 of the display panel 110, there can occur an area where the spacing between the plurality of light emitting devices ED is not uniform due to process deviation. If the spacing between the plurality of light emitting devices ED is not uniform, an emission areas of each of the plurality of light emitting devices ED can be arranged unevenly, and thus a mura can be visible to the user. Accordingly, since the third optical layer 1517c is arranged to uniformly diffuse light over the plurality of light emitting devices ED, it is possible to reduce light emitted from some of the light emitting devices ED from being visible as a mura. Accordingly, since the light emitted from the plurality of light emitting devices EDs is evenly diffused by the third optical layer 1517c and extracted to the outside of the display device 100, the luminance uniformity of the display device 100 can be improved.

The third optical layer 1517c can be composed of an organic insulating material in which fine particles are dispersed. For example, the third optical layer 1517c can be composed of siloxane in which fine metal particles such as titanium dioxide (TiO2) particles are dispersed but the embodiments of the present disclosure are not limited thereto. For example, the third optical layer 1517c can be composed of the same material as the first optical layer 1517a. For example, the third optical layer 1517c can be a diffusion layer or an upper diffusion layer.

Light from a plurality of light emitting devices ED can be scattered by fine particles dispersed in a third optical layer 1517c and emitted to the outside of the display device 100. The third optical layer 1517c can evenly mix light emitted from a plurality of light emitting devices ED, thereby further improving the luminance uniformity of the display device 100. In addition, the light extraction efficiency of the display device 100 can be improved by the light scattered from the plurality of fine particles, thereby enabling the display device 100 to be driven at low power.

A black matrix BM can be arranged on the row line RL, the first optical layer 1517a, the second optical layer 1517b, and the third optical layer 1517c in the display area DA. For example, the black matrix BM can fill a contact hole of the second optical layer 1517b. The black matrix BM can be configured to cover the display area DA, so that the color mixing of light and external light reflection of the plurality of sub-pixels can be reduced. For example, the black matrix BM can also be arranged in the contact hole where the row line RL and the row connection electrode RCE are connected, so that light leakage between the neighboring plurality of sub-pixels can be prevented or reduced. For example, the black matrix BM can be composed of an opaque material. For example, the black matrix BM can be an organic insulating material to which a black pigment or a black dye is added.

A cover layer 1518 can be arranged on the black matrix BM in the display area DA. The cover layer 1518 can protect a configuration under the cover layer 1518. For example, the cover layer 1518 can be composed of an organic insulating material. For example, the cover layer 1518 can be composed of a photo resist, polyimide (PI), or photo acryl-based material. For example, the cover layer 1518 can be an overcoating layer or an insulating layer.

A polarizing layer 114 can be arranged on the cover layer 1518 via a first adhesive layer 112. A cover member 118 can be arranged on the polarizing layer 114 via a second adhesive layer 116. For example, the first adhesive layer 112 and the second adhesive layer 116 can include an optically clear adhesive (OCA), an optically clear resin (OCR), or a pressure sensitive adhesive PSA.

A plurality of pads PD can be arranged on a third insulating layer 1515c in a second non-display area NDA2. For example, at least a portion of the plurality of pads PD can be exposed from a passivation layer 1516. For example, the plurality of pads PD can be electrically connected to a fourth pad connection pattern PCP4 through a contact hole of the third insulating layer 1515c.

An adhesive layer ACF can be arranged on the plurality of pads PD. The adhesive layer ACF can be an adhesive layer in which conductive balls are dispersed in an insulating material. The adhesive layer ACF can be disposed between a plurality of pads PD and a flexible printed circuit 102, so that the flexible printed circuit 102 can be attached or bonded to the plurality of pads PD. For example, the adhesive layer ACF can be an anisotropic conductive film ACF.

A flexible printed circuit 102 can be disposed on the adhesive layer ACF. The flexible printed circuit 102 can be electrically connected to the plurality of pads PD through the adhesive layer ACF. Accordingly, a signal supplied from the flexible printed circuit 102 can be transmitted to a driver DRV of a display area DA through the plurality of pads PD, the fourth pad connection pattern PCP4, the third pad connection pattern PCP3, the second pad connection pattern PCP2, and the first pad connection pattern PCP1.

The display panel 110 according to the embodiments of the present disclosure can include a substrate 210, a layer stack 1410 on a plurality of drivers DRV disposed on the substrate 210, a first optical layer 1517a disposed between a plurality of light emitting devices EDa, EDb and EDc on the layer stack 1410, an adhesive layer 116 disposed on the plurality of light emitting devices EDa, EDb and EDc and the first optical layer 1517a, and a cover member 118 disposed on the adhesive layer 116.

A plurality of column lines CL can be disposed between the layer stack 1410 and the plurality of light emitting devices EDa, EDb and EDc. A plurality of row lines RL can be arranged on a plurality of light emitting devices EDa, EDb and EDc and a first optical layer 1517a. A plurality of row lines RL can be arranged between a plurality of light emitting devices EDa, EDb and EDc, an optical layer 1517a, and an adhesive layer 116.

A layer stack 1410 can include a plurality of protection layers 1513a, 1513b and 1514 arranged on the side and upper surface of each of a plurality of drivers DRV, a plurality of insulating layers 1515a, 1515b and 1515c arranged on the plurality of protection layers 1513a, 1513b and 1514, and a bank BN arranged on the plurality of insulating layers.

The plurality of protection layers 1513a, 1513b and 1514 can further include a side protection layer 1513 disposed on each side of the plurality of drivers DRV and an upper protection layer 1514 disposed on the upper surface of each of the plurality of drivers DR.

The side protection layer 1513 can include a first protection layer 1513a disposed on the substrate 210 and a second protection layer 1513b disposed on the first protection layer 1513a. The upper protection layer 1514 can include a second protection layer 1513b and a third protection layer 1514 disposed on the plurality of drivers DRV.

The plurality of insulating layers 1515a, 1515b and 1515c can include a first insulating layer 1515a disposed on the upper protection layer 1514, and a second insulating layer 1515b disposed on the first insulating layer 1515a. The plurality of insulating layers 1515a, 1515b and 1515c can further include a third insulating layer 1515c disposed on the second insulating layer1515b.

Each of the plurality of light emitting devices EDa, EDb and EDc can be disposed on the bank BNK and positioned in an opening of the optical layer 1517a.

At least a portion of each of the plurality of column lines CL can extend onto the bank BNK on the plurality of insulating layers 1515a, 1515b and 1515c. Each of the plurality of row lines RL can be arranged on the optical layer 1517a and the plurality of light emitting devices EDa, EDb and EDc.

A first electrode Ecl of each of the plurality of light emitting devices EDa, EDb and EDc can be electrically connected to at least a portion of a column line CL extending onto the bank BNK among the plurality of column lines CL. A second electrode Erl of each of the plurality of light emitting devices EDa, EDb and EDc can be electrically connected to one of the plurality of row lines RL.

The display panel 110 can include a plurality of line connection patterns LCPs that connect each of a plurality of lines including a plurality of row lines RL and a plurality of column lines CL to a plurality of drivers DR.

The plurality of line connection patterns LCPs can include a first line connection pattern LCP1 disposed on a side protection layer 1513, a second line connection pattern LCP2 disposed on an upper protection layer 1514 and electrically connected to the first line connection pattern LCP1 through a hole in the upper protection layer 1514, a third line connection pattern LCP3 disposed on a first insulating layer 1515a and electrically connected to the second line connection pattern LCP2 through a hole in the first insulating layer 1515a, and a fourth line connection pattern LCP4 disposed on a second insulating layer 1515b and electrically connected to the third line connection pattern LCP3 through a hole in the second insulating layer 1515b.

The first line connection pattern LCP1 can be electrically connected to one of the plurality of drivers DRV. The fourth line connection pattern LCP4 can be electrically connected to at least one second electrode Erl of the plurality of light emitting devices EDa, EDb and EDc, or can be electrically connected to at least one first electrode Ecl of the plurality of light emitting devices EDa, EDb and EDc.

The side protection layer 1513 arranged on each side of the plurality of drivers DRV can include two or more organic layers.

The first and second protection layers 1513a and 1513b as the side protection layer 1513, the third protection layer 1514 as the upper protection layer 1514, and the first to third insulating layers 1515a, 1515b and 1515c can each be composed of organic layers.

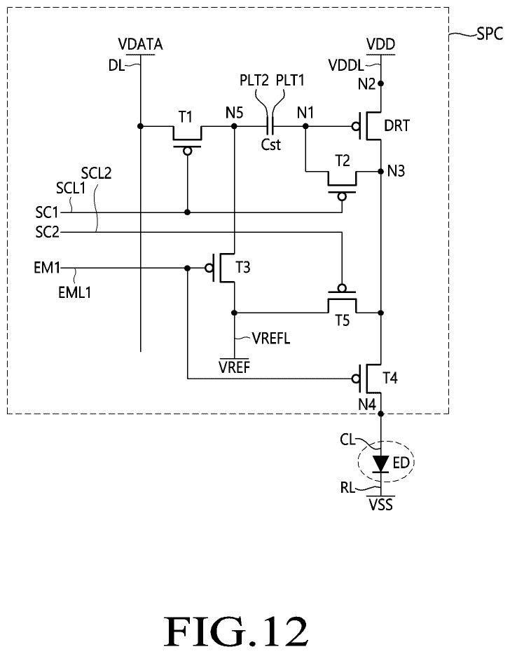

FIG. 12 is an equivalent circuit of a sub-pixel of a display panel 110 according to embodiments of the present disclosure. FIGS. 1 to 11 are also referred to in the following description.

Referring to FIG. 12, the sub-pixel of the display panel 110 according to the embodiments of the present disclosure can include a light emitting device ED and a sub-pixel circuit SPC for driving the light emitting device ED.

The light emitting device ED can be disposed on the substrate 210 within the display panel 110. For example, the light emitting device ED can be disposed within the display panel 110, but can also be disposed outside a driver DRV. As an example, the sub-pixel circuit SPC can be included in the driver DRV of the unit driving area UDA in which the light emitting device ED is disposed. As another example, the sub-pixel circuit SPC can be disposed outside the driver DRV within the display panel 110.

The light emitting device ED can include a first electrode and a second electrode, and an emission layer between the first electrode and the second electrode. For example, the first electrode of the light emitting device ED can be an anode electrode, and the second electrode of the light emitting device ED can be a cathode electrode. The first electrode of the light emitting device ED can be electrically connected to a column line CL, and the second electrode of the light emitting device ED can be electrically connected to a row line RL. A low-potential voltage VSS can be applied to the second electrode of the light emitting device ED.

The sub-pixel circuit SPC can be connected to the first electrode of the light emitting device ED. The sub-pixel circuit SPC can be connected to a column line CL electrically connected to the first electrode of the light emitting device ED. The sub-pixel circuit SPC can include a column driver C-DRV included in a driver DRV of a unit driving area UDA in which the light emitting device ED is disposed.

The sub-pixel circuit SPC can also be connected to the second electrode of the light emitting device ED. The sub-pixel circuit SPC can be connected to a row line RL electrically connected to the second electrode of the light emitting device ED. The sub-pixel circuit SPC can further include a row driver R-DRV included in a driver DRV of a unit driving area UDA in which the light emitting device ED is disposed.

For example, the sub-pixel circuit SPC can include a plurality of electrical nodes such as the first to fifth nodes N1 to N5, and can include a driving transistor DRT, the first to fifth transistors T1 to T5, and a storage capacitor Cst.

The storage capacitor Cst can include a first plate PLT1 and a second plate PLT2. The storage capacitor Cst can be connected between the first node N1 and the fifth node N5. The first plate PLT1 can correspond to the first node N1, and the second plate PLT2 can correspond to the fifth node N5.

The driving transistor DRT can control the connection between a second node N2 and a third node N3 according to a voltage of the first node N1. The first node N1 can correspond to a gate electrode of the driving transistor DRT. The second node N2 can correspond to the source electrode or the drain electrode of the driving transistor DRT, and can be electrically connected to the high-potential voltage line VDDL to which the high-potential voltage VDD is applied. The third node N3 can correspond to the drain electrode or the source electrode of the driving transistor DRT. The first node N1 can correspond to the first plate PLT1 of the storage capacitor Cst.

A first transistor T1 can control the connection between a data line DL and the fifth node N5 according to a first scan signal SC1 supplied from a first scan line SCL1. A gate electrode of the first transistor T1 can be electrically connected to the first scan line SCL1, and a source electrode or a drain electrode of the first transistor T1 can be electrically connected to the data line DL to which a data voltage VDATA is applied. The drain electrode or the source electrode of the first transistor T1 can correspond to the fifth node N5.

A second transistor T2 can control the connection between the first node N1 and the third node N3 according to the first scan signal SC1 supplied from the first scan line SCL1. A gate electrode of the second transistor T2 can be electrically connected to the first scan line SCL1, a source electrode or a drain electrode of the second transistor T2 can correspond to the third node N3, and the drain electrode or the source electrode of the second transistor T2 can correspond to the first node N1.

A third transistor T3 can control the connection between a reference voltage line VREFL to which the reference voltage VREF is applied and the fifth node N5 according to a first emission control signal EM1 supplied from a first emission control line EML1. The fifth node N5 can correspond to the second plate PLT2 of the storage capacitor Cst.

A fourth transistor T4 can control the connection between the third node N3 and a fourth node N4 according to the first emission control signal EM1 supplied from the first emission control line EML1. The fourth transistor T4 can correspond to a first emission control transistor EMT1 of FIG. 5. A gate electrode of the fourth transistor T4 can be electrically connected to the first emission control line EML1, and a source electrode or a drain electrode of the fourth transistor T4 can correspond to the third node N3. The drain electrode or the source electrode of the fourth transistor T4 can correspond to the fourth node N4. The fourth node N4 can be electrically connected to the column line CL.

A fifth transistor T5 can control the connection between the reference voltage line VREFL and the third node N3 according to a second scan signal SC2 supplied from a second scan line SCL2. A gate electrode of the fifth transistor T5 can be electrically connected to the second scan line SCL2, a source electrode or a drain electrode of the fifth transistor T5 can be electrically connected to the reference voltage line VREFL, and the drain electrode or the source electrode of the fifth transistor T5 can correspond to the third node N3.

The driving transistor DRT and each of the first to fifth transistors T5 can be a p-type transistor or an n-type transistor. For example, as illustrated in FIG. 12, the driving transistor DRT and the first to fifth transistors T5 can all be p-type transistors. As another example, the driving transistor DRT and the first to fifth transistors T5 can all be n-type transistors. As another example, the driving transistor DRT and the first to fifth transistors T5 can be a mixture of n-type transistors and p-type transistors.

The sub-pixel circuit SPC illustrated in FIG. 12 is only an example, and can be implemented in various forms.

The structure and operation related to the display function of the display device 100 according to the embodiments of the present disclosure have been described above.

The display device 100 according to the embodiments of the present disclosure can provide not only the display function but also the touch sensing function. Hereinafter, it will be described the structure and operation related to the touch sensing function of the display device 100 according to the embodiments of the present disclosure. In the following description, reference can be made to FIGS. 1 to 12 together.

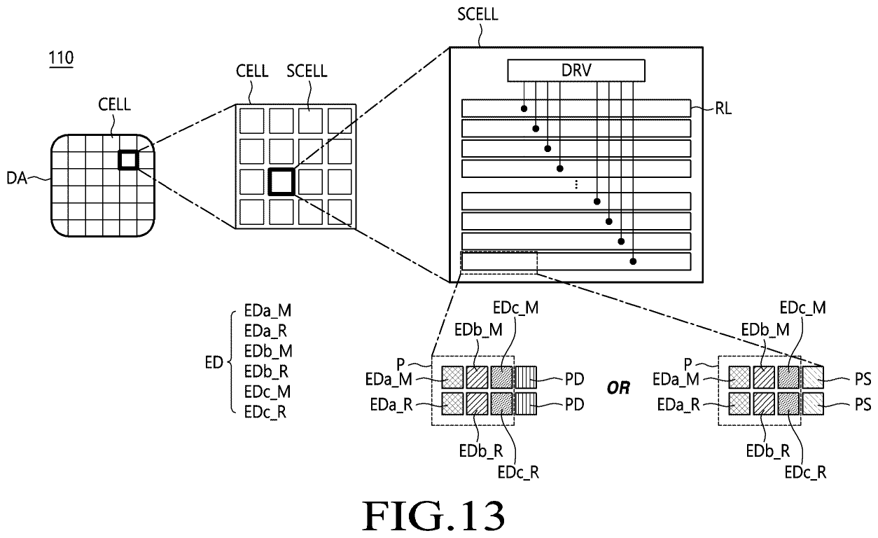

FIG. 13 illustrates an optical touch sensing structure of a display device 100 according to embodiments of the present disclosure.

Referring to FIG. 13, the display device 100 according to the embodiments of the present disclosure can provide an optical touch sensing function. The display device 100 according to the embodiments of the present disclosure can include an optical touch sensor, and the optical touch sensor can include an optical driving device PD and an optical detection device PS.

The optical driving device PD can emit a specific light of a first wavelength band. The specific light emitted from the optical driving device PD can be emitted to the outside of the display device 100 and can be reflected by a touch point (e.g., a finger, a pen, etc.) located outside the display device 100. The specific light reflected by the touch point can be incident into the inside of the display device 100.

The optical detection device PS can detect a specific light incident into the inside of the display device 100. The presence or absence of a touch or the touch location can be detected depending on whether a specific light is detected by the optical detection device PS.

The optical driving device PD and the optical detection device PS can be disposed on the display panel 110. The positions where the optical driving device PD and the optical detection device PS are disposed within the display panel 110 will be described by example below.

The display area DA of the display panel 110 according to the embodiments of the present disclosure can include a plurality of cells CELL. Each of the plurality of cells CELL can include a plurality of sub-cells SCELL corresponding to a plurality of drivers DRV. For example, one driver DRV can be disposed in each of the plurality of sub-cells SCELL. Here, the sub-cell SCELL can be the same as the unit driving area UDA of FIG. 3. For example, the unit driving area UDA is an area driven by one driver DRV from a display driving perspective, and the sub-cell SCELL can be an area driven by one driver DRV from a touch driving perspective.

Each of the plurality of sub-cells SCELL can include two or more row lines RL. Each of the two or more row lines RL can overlap with at least one pixel P. Each pixel P can include two or more light emitting devices ED. For example, each pixel P can include a (main) light emitting device EDa_M emitting a first color light, a (main) light emitting device EDb_M emitting a second color light, and a (main) light emitting device EDc_M emitting a third color light. Each pixel P can further include a redundancy light emitting device EDa_R emitting a first color light, a redundancy light emitting device EDb_R emitting a second color light, and a redundancy light emitting device EDc_R emitting a third color light.

At least one optical driving device PD can be disposed adjacent to at least one pixel P. At least one optical detection device PS can be disposed adjacent to at least one pixel P.

A display device 100 according to embodiments of the present disclosure can include a substrate 210, a plurality of light emitting devices ED disposed on the substrate 210 and positioned in a display area DA, a plurality of column lines CL electrically connected to a first electrode of each of the plurality of light emitting devices ED, a plurality of row lines RL electrically connected to a second electrode of each of the plurality of light emitting devices ED, a plurality of drivers DRV electrically connected to the plurality of column lines CL and the plurality of row lines RL, an optical driving device PD disposed on the substrate 210, positioned in the display area DA, overlapping a first row line RL1 of the plurality of row lines RL, and emitting a specific light of a first wavelength band according to a voltage difference between both ends of the optical driving device, and an optical detection device PS disposed on the substrate 210 and detecting the specific light reflected from the outside and incident inside.

Each of the plurality of column lines CL can be electrically connected to a first electrode of each of two or more light emitting devices ED arranged in the same column. Each of the plurality of row lines RL can be electrically connected to a second electrode of each of two or more light emitting devices ED arranged in the same row.

For example, a first wavelength band of a specific light emitted from the optical driving devices PD can be a wavelength band different from a wavelength band of light emitted from the plurality of light emitting devices ED.

For example, the first wavelength band of the specific light emitted from the optical driving devices PD can be a wavelength band different from the visible light wavelength band. For example, the first wavelength band can be an infrared wavelength band. For another example, the first wavelength band can be an ultraviolet wavelength band.

For example, among the plurality of cells CELL, only the optical driving device PD can be arranged in some cells CELL, and only the optical detection device PS can be arranged in other cells CELL. For example, the optical driving device PD and the optical detection device PS can be arranged in units of cells.

For another example, among the plurality of sub-cells SCELL, only the optical driving device PD can be arranged in some sub-cells SCELL, and only the optical detection device PS can be arranged in other sub-cells SCELL. For example, the optical driving devices PD and the optical detection device PS can be arranged in units of sub-cells.

The optical touch sensor according to the embodiments of the present disclosure can include an optical driving device PD and an optical detection device PS. For example, the optical driving device PD can be implemented as a light-emitting diode that emits a specific light of a first wavelength band, and the optical detection device PS can be implemented as a photodiode that generates current in response to light.

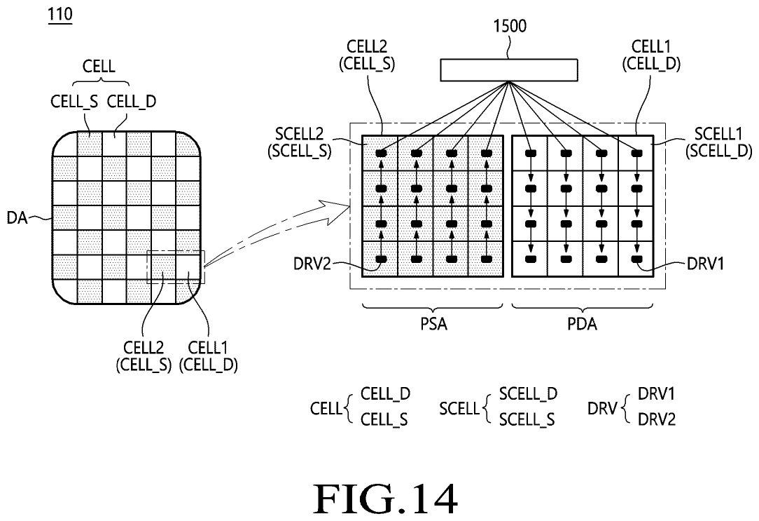

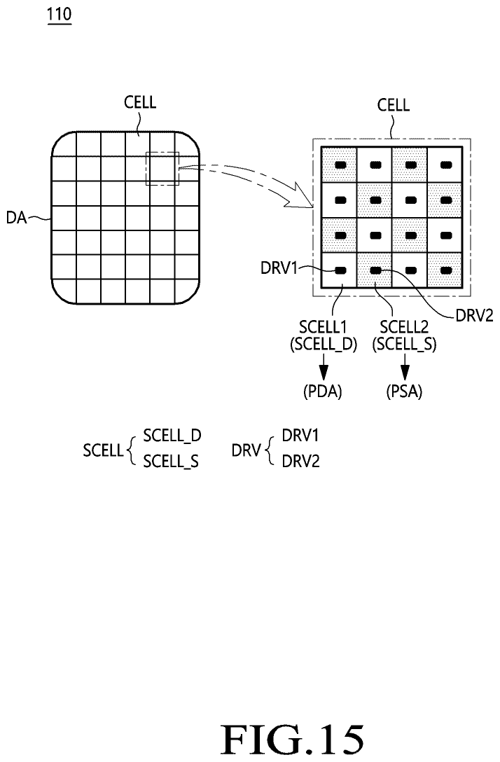

Hereinafter, it will be described a case in which the optical driving device PD and the optical detection device PS are arranged in units of cells with reference to FIG. 14, and a case in which the optical driving device PD and the optical detection device PS are arranged in units of sub-cells with reference to FIG. 15.

FIG. 14 illustrates an optical driving area PDA and an optical sensing area PSA configured in units of cells in a display device 100 according to the embodiments of the present disclosure.

Referring to FIG. 14, according to the display device 100 according to the embodiments of the present disclosure, the optical driving device PD and the optical detection device PS can be arranged in units of cells.

The display area DA of the display panel 110 can include a plurality of cells CELL.

Each of the plurality of cells CELL can include a plurality of sub-cells SCELL corresponding to a plurality of drivers DRV.

Among the plurality of cells CELL, some of the cells CELL can be optical driving cells CELL_D in which the optical driving device PD is arranged, and other cells CELL can be optical detection cells CELL_S in which the optical detection device PS is arranged.

For example, among the plurality of cells CELL, two cells CELL adjacent in a horizontal direction (e.g., row direction) can be an optical driving cell CELL_D and an optical detection cell CELL_S. Among the plurality of cells CELL, two cells CELL adjacent in a vertical direction (e.g., column direction) can be an optical driving cell CELL_D and an optical detection cell CELL_S.

For example, the plurality of cells CELL can include a first cell CELL1 and a second cell CELL2. The first cell CELL1 can be an optical driving cell CELL_D. The second cell CELL2 can be an optical detection cell CELL_S. The first cell CELL1 and the second cell CELL2 can be cells adjacent in the first direction or the second direction. For example, the first direction can be a row direction, and the second direction can be a column direction. In another example, the first direction can be the column direction and the second direction can be the row direction.

The first cell CELL1 can include a plurality of first sub-cells SCELL1. Each of the plurality of first sub-cells SCELL1 can include a first driver DRV1. The plurality of first sub-cells SCELL1 can refer to a plurality of sub-cells SCELL included in the first cell CELL1. The first driver DRV1 can refer to a driver DRV included in the first sub-cell SCELL1.

The second cell CELL2 can include a plurality of second sub-cells SCELL2. Each of the plurality of second sub-cells SCELL2 can include a second driver DRV2. The plurality of second sub-cells SCELL2 can refer to a plurality of sub-cells SCELL included in the second cell CELL2. The second driver DRV2 can refer to a driver DRV included in the second sub-cell SCELL2.

At least one of the plurality of first sub-cells SCELL1 included in the first cell CELL1 can be an optical driving sub-cell SCELL_D, and can include an optical driving device PD. An optical detection device PS may not be arranged in the plurality of first sub-cells SCELL1.

The first driver DRV1 included in all or part of the plurality of first sub-cells SCELL1 can drive the optical driving device PD to cause the optical driving device PD to emit a specific light.

At least one of the plurality of second sub-cells SCELL2 included in the second cell CELL2 can be an optical sensing sub-cell SCELL_S, and can include an optical detection device PS. An optical driving device PD may not be arranged in the plurality of second sub-cells SCELL2.

The second driver DRV2 included in all or part of the plurality of second sub-cells SCELL2 can perform light detection through the optical detection device PS. Here, a detection of light or a magnitude of light detection (e.g., the amount of light detection) can vary depending on an occurrence of a touch or a touch position.

The display device 100 according to the embodiments of the present disclosure can further include a controller 1500 connected to the plurality of drivers DRV. For example, the controller 1500 can be implemented as a micro controller unit (MCU).

The controller 1500 can control the plurality of first drivers DRV1 and the plurality of second drivers DRV2.

The controller 1500 can drive the optical driving device PD disposed in the first sub-cell SCELL1 by controlling the plurality of first drivers DRV1. When the optical driving device PD is driven, a specific light can be emitted from the optical driving device PD.

If a specific light is emitted from the optical driving device PD disposed in the first sub-cell SCELL1, the specific light can be reflected from a touch point (e.g., a finger, a pen, etc.) outside the display device 100 and can be incident into the inside of the display device 100.

The controller 1500 can control the plurality of second drivers DRV2, so that the second drivers DRV2 can detect a sensing voltage of a sensing node in the second sub-cell SCELL2. The second drivers DRV2 can supply sensing data to the controller 1500 based on the detected sensing voltage. The controller 1500 can determine the presence or absence of a touch and/or the touch location based on the sensing data.

The sensing node in the second sub-cell SCELL2 can have a sensing voltage according to the touch by the current (e.g., forward current) generated through the optical detection device PS arranged in the second sub-cell SCELL2. The forward current can be generated in the optical detection device PS arranged in the second sub-cell SCELL2 by the specific light incident into the interior of the display device 100.

As described above, among the plurality of cells CELL, the first cell CELL1 can be an optical driving cell CELL_D in which only an optical driving device PD is disposed without an optical detection device PS, and the second cell CELL2 can be an optical detection cell CELL_S in which only an optical detection device PS is disposed without an optical driving device PD. Accordingly, the first cell CELL1 can correspond to an optical driving area PDA, and the second cell CELL2 can correspond to an optical sensing area PSA.

FIG. 15 illustrates an optical driving area PDA and an optical sensing area PSA configured in units of sub-cells in a display device 100 according to embodiments of the present disclosure.

Referring to FIG. 15, according to the display device 100 according to embodiments of the present disclosure, the optical driving device PD and the optical detection device PS can be disposed in sub-cell units.

The display area DA of the display panel 110 can include a plurality of cells CELL.

Each of the plurality of cells CELL can include a plurality of sub-cells SCELL corresponding to a plurality of drivers DRV.

Among the plurality of sub-cells SCELL included in each of the plurality of cells CELL, some of the sub-cells SCELL can be optical driving sub-cells SCELL_D in which an optical driving device PD is arranged, and other sub-cells SCELL can be optical sensing sub-cells SCELL_S in which an optical detection device PS is arranged.

For example, the plurality of sub-cells SCELL can include a first sub-cell SCELL1 and a second sub-cell SCELL2. The first sub-cell SCELL1 can be an optical driving sub-cell SCELL_D. The second sub-cell SCELL2 can be an optical sensing sub-cell SCELL_S. For example, the first sub-cell SCELL1 and the second sub-cell SCELL2 can be adjacent cells in the first direction or the second direction. For example, the first direction can be a row direction, and the second direction can be a column direction. In another example, the first direction can be a column direction and the second direction can be a row direction.

Among the plurality of sub-cells SCELL included in each of the plurality of cells CELL, the first sub-cell SCELL1 can be an optical driving sub-cell SCELL_D, and can include an optical driving device PD. The first sub-cell SCELL1 may not include an optical detection device PS.

A first driver DRV1 included in the first sub-cell SCELL1 can drive the optical driving device PD included in the first sub-cell SCELL1 to cause the optical driving device PD to emit a specific light.

Among the plurality of sub-cells SCELL included in each of the plurality of cells CELL, the second sub-cell SCELL2 can be an optical sensing sub-cell SCELL_S, and can include an optical detection device PS. The second sub-cell SCELL2 may not include an optical driving device PD.

A second driver DRV2 included in the second sub-cell SCELL2 can perform light detection through the optical detection device PS included in the second sub-cell SCELL2. Here, the detection of light or a magnitude of light detection (e.g., the amount of light detection) can vary depending on a presence or absence of a touch or a touch location.

As described above, among the plurality of sub-cells SCELL included in each of the plurality of cells CELL, the first sub-cell SCELL1 can be an optical driving sub-cell SCELL_D in which only an optical driving device PD is disposed without an optical detection device PS, and the second sub-cell SCELL2 can be an optical sensing sub-cell SCELL_S in which only an optical detection device PS is disposed without an optical driving device PD. Accordingly, the first sub-cell SCELL1 can correspond to an optical driving area PDA, and the second sub-cell SCELL2 can correspond to an optical sensing area PSA.

As described above, each of the plurality of cells CELL can include an optical driving device PD and an optical detection device PS. For example, each of the plurality of cells CELL can include at least one optical driving area PDA and at least one optical sensing area PSA.

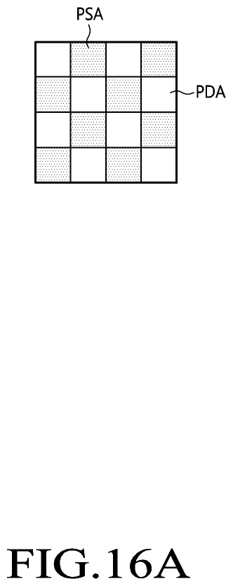

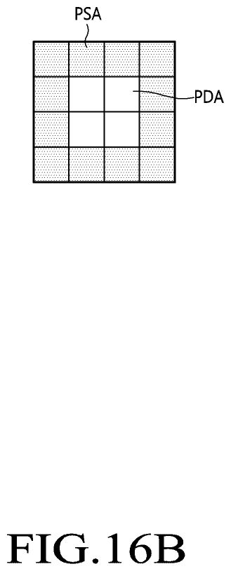

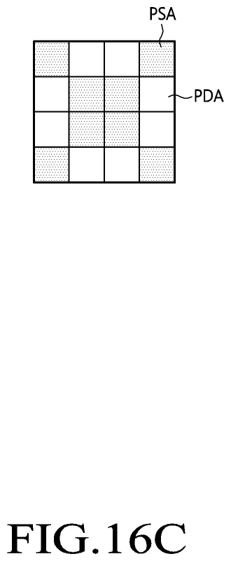

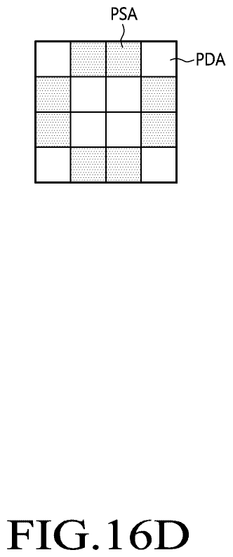

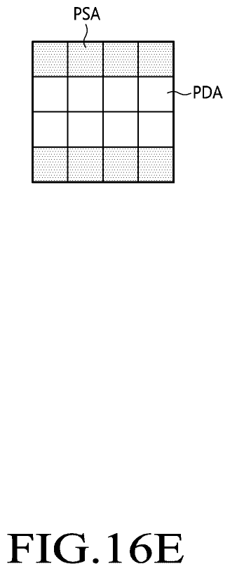

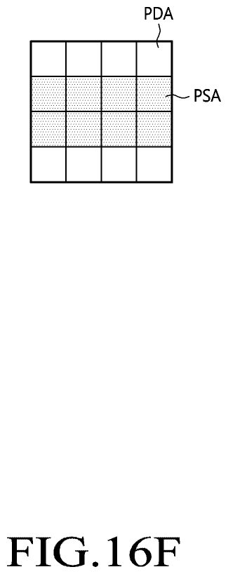

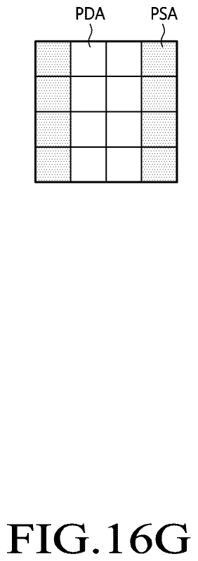

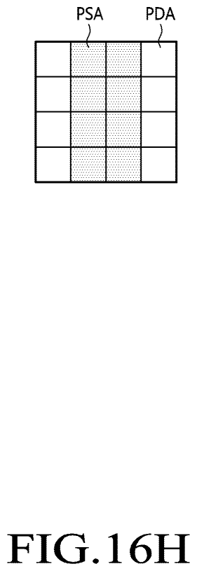

FIGS. 16A to 16H illustrate examples of configuring an optical driving area PDA and an optical sensing area PSA in a display device 100 according to embodiments of the present disclosure.

Referring to FIGS. 16A to 16H, the optical driving area PDA and the optical sensing area PSA can be arranged within a specific area. A specific area can include 16 sub-areas, and an optical driving area PDA or an optical sensing area PSA can be assigned to each of the 16 sub-areas.

As in FIG. 14, if the optical driving area PDA and the optical sensing area PSA are configured in units of cells, a specific area can be a part of the display area DA, and each of the 16 sub-areas can be one cell CELL.

As shown in FIG. 15, if the optical driving area PDA and the optical sensing area PSA are configured as sub-cell units, a specific area can be one cell CELL included in the display area DA, and each of the 16 sub-areas can be a sub-cell SCELL included in one cell CELL.

Referring to FIG. 16A, within a specific area, the optical driving area PDA and the optical sensing area PSA can be arranged alternately. The optical driving area PDA and the optical sensing area PSA can be arranged adjacently in the row direction and the column direction.

Referring to FIG. 16B, within a specific area, the optical driving area PDA can be arranged in the center, and the optical sensing area PSA can be arranged surrounding the optical driving area PDA.

Referring to FIG. 16C, within a specific area, the optical sensing area PSA can be arranged in the center, the optical driving area PDA can be arranged on the left and right sides of the center, the optical driving area PDA can be arranged on the upper and lower sides of the center, and the optical sensing area PSA can be arranged at the corners.

Referring to FIG. 16D, within a specific area, the optical driving area PDA can be arranged in the center, the optical sensing area PSA can be arranged on the left and right sides of the center, the optical sensing area PSA can be arranged on the upper and lower sides of the center, and the optical driving area PDA can be arranged at the corners.

Referring to FIG. 16E, within a specific area, the optical driving area PDA can be arranged in the center, and the optical sensing area PSA can be arranged on the upper and lower sides of the center.

Referring to FIG. 16F, within a specific area, the optical sensing area PSA can be arranged in the center and the optical driving area PDA can be arranged on the upper and lower sides of the center.

Referring to FIG. 16G, within a specific area, the optical driving area PDA can be arranged in the center and the optical sensing area PSA can be arranged on the left and right sides of the center.

Referring to FIG. 16H, within a specific area, the optical sensing area PSA can be arranged in the center, and the optical driving area PDA can be arranged on the left and right sides of the center.

The arrangement of the optical driving areas PDA and optical sensing areas PSA illustrated in FIGS. 16A to 16H is only an example, and can be variously modified in consideration of optical touch sensing performance (or touch sensing precision) or power consumption reduction.

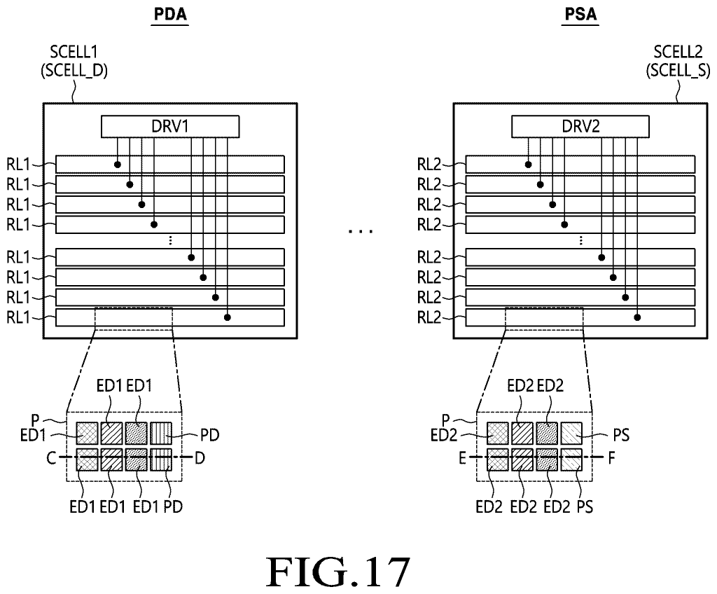

FIG. 17 is a diagram illustrating a first sub-cell SCELL1 included as an optical driving sub-cell SCELL_D in an optical driving area PDA and a second sub-cell SCELL2 included as an optical sensing sub-cell SCELL_S in an optical sensing area PSA in a display device 100 according to embodiments of the present disclosure.

Referring to FIG. 17a, display panel 110 of a display device 100 according to embodiments of the present disclosure can include a first sub-cell SCELL1 included as an optical driving sub-cell SCELL_D in an optical driving area PDA and a second sub-cell SCELL2 included as an optical sensing sub-cell SCELL_S in an optical sensing area PSA.

The first sub-cell SCELL1 can include a plurality of first light emitting devices ED1, two or more first row lines RL1, and a first driver DRV1. The second sub-cell SCELL2 can include a plurality of second light emitting devices ED2, two or more second row lines RL2, and a second driver DRV2.

The first driver DRV1 can be electrically connected to two or more first row lines RL1. The second driver DRV2 can be electrically connected to two or more second row lines RL2.

Each of the two or more first row lines RL1 can overlap with two or more first light emitting devices ED1. Each of the two or more second row lines RL2 can overlap with two or more second light emitting devices ED2.

According to the above, the plurality of row lines RL arranged on the display panel 110 can include a first row line RL1 and a second row line RL2. The plurality of drivers DRV disposed on the display panel 110 can include a first driver DRV1 electrically connected to the first row line RL1 and a second driver DRV2 electrically connected to the second row line RL2.

The first sub-cell SCELL1 can include at least one optical driving device PD. The at least one optical driving device PD can be disposed to overlap with all or part of the plurality of first row lines RL1.

The optical driving device PD can be disposed on a side of the first light emitting device ED1 overlapping with the first row line RL1. The optical driving device PD can include an anode electrode and a cathode electrode.

The first driver DRV1 can drive the optical driving device PD.

The first driver DRV1 can generate a voltage difference between the anode electrode and the cathode electrode of the optical driving device PD. Accordingly, the optical driving device PD can emit a specific light of a first wavelength band according to the voltage difference between the two ends (e.g., the anode and cathode electrodes) of the optical driving device PD).

The second sub-cell SCELL2 can include at least one optical detection device PS. The at least one optical detection device PS can be arranged to overlap with all or part of a plurality of second row lines RL2.

The optical detection device PS can be arranged on a side of the second light emitting device ED2 that overlaps with the second row line RL2. The optical detection device PS can include an anode electrode and a cathode electrode.

The second driver DRV2 can drive the optical detection device PS.

The second driver DRV2 can control light detection through the optical detection device PS, and generate sensing data based on a sensing signal corresponding to the presence or absence of light detection.

The display device 100 according to the embodiments of the present disclosure can include a substrate 210, a plurality of light emitting devices ED disposed on the substrate 210 and positioned in the display area DA, a plurality of drivers DRV for driving the plurality of light emitting devices ED, an optical driving device PD disposed on the substrate 210, positioned in the display area DA, and emitting a specific light of a first wavelength band, and an optical detection device PS disposed on the substrate 210, positioned in the display area DA, and detecting the specific light reflected from the outside and incident inside.

The optical driving device PD can be driven by a first driver DRV1 among the plurality of drivers DRV, and the optical detection device PS can be driven by a second driver DRV2 among the plurality of drivers DRV.

The plurality of drivers DRV can be disposed on the substrate 210 and positioned in the display area DA.

The specific light emitted from the optical driving device PD can have a wavelength band different from the wavelength band of the light emitted from the plurality of light emitting devices ED.

The optical driving device PD can be positioned on the side of the first light emitting device ED1 among the plurality of light emitting devices ED, and the optical detection device PS can be positioned on the side of the second light emitting device ED2 among the plurality of light emitting devices ED.

Hereinafter, the optical touch sensing circuit will be described in more detail in connection with the sub-pixel circuit.

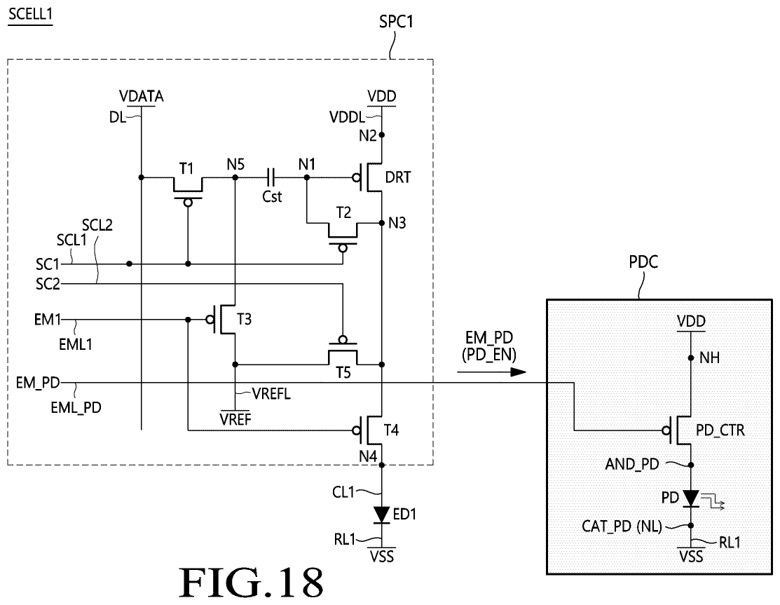

FIG. 18 illustrates a first sub-cell SCELL1 included as an optical driving sub-cell SCELL_D in an optical driving area PDA in a display device 100 according to embodiments of the present disclosure.

Referring to FIG. 18, the first sub-cell SCELL1 included as an optical driving sub-cell SCELL_D in an optical driving area PDA can include an optical driving circuit PDC. The first sub-cell SCELL1 can further include a first light emitting device ED1 and a first sub-pixel circuit SPC1 for driving the first light emitting device ED1. The first sub-pixel circuit SPC1 is the same as the sub-pixel circuit SPC of FIG. 12. Therefore, the description of the first sub-pixel circuit SPC1 will be omitted.

The optical driving circuit PDC can include an optical driving device PD. The optical driving device PD can include an anode electrode AND_PD and a cathode electrode CAT_PD.

The cathode electrode CAT_PD of the optical driving device PD can be electrically connected to a low-potential voltage node NL to which a low-potential voltage VSS is applied. For example, the low-potential voltage node NL can be electrically connected to the first row line RL1.

The first driver DRV1 arranged in the first sub-cell SCELL1 among the plurality of drivers DRV can be electrically connected to the first row line RL1.

The first driver DRV1 can generate a voltage difference between the anode electrode AND_PD and the cathode electrode CAT_PD of the optical driving device PD. If the voltage difference between the anode electrode AND_PD and the cathode electrode CAT_PD of the optical driving device PD occurs, the optical driving device PD can emit a specific light of the first wavelength band.

The first row line RL1 arranged in the first sub-cell SCELL1 can be electrically connected to a second electrode of each of two or more first light emitting devices ED1 among the plurality of light emitting devices ED. The first row line RL1 arranged in the first sub-cell SCELL1 can be electrically connected to the cathode electrode CAT_PD of the optical driving device PD.

The optical driving circuit PDC can further include an optical driving control transistor PD_CTR. The optical driving control transistor PD_CTR can be connected between a high-potential voltage node NH to which a high-potential voltage VDD is applied and an anode electrode AND_PD of the optical driving device PD. The optical driving control transistor PD_CTR can control the connection between the high-potential voltage node NH and the anode electrode AND_PD of the optical driving device PD according to a driving enable control signal PD_EN.

For example, the optical driving device PD can be arranged in the first sub-cell SCELL1, but can be arranged outside the first driver DRV1. The optical driving control transistor PD_CTR can be included within the first driver DRV1.

The first light emitting device ED1 can be disposed in the first sub-cell SCELL1, but can be disposed outside the first driver DRV1. The first sub-pixel circuit SPC1 for driving the first light emitting device ED1 can be included within the first driver DRV1.

The driving enable control signal PD_EN applied to a gate node of the optical driving control transistor PD_CTR can be an optical driving emission control signal EM_PD that controls the emission of the optical driving control transistor PD_CTR. The optical driving emission control signal EM_PD can be transmitted to the gate node of the optical driving control transistor PD_CTR through an optical driving emission control signal line EML_PD.

If the optical driving control transistor PD_CTR is turned on by the driving enable control signal PD_EN, a high-potential voltage VDD can be applied to the anode electrode AND_PD of the optical driving device PD. In this case, the high-potential voltage VDD can be applied to the anode electrode AND_PD of the optical driving device PD, and the low-potential voltage VSS can be applied to the cathode electrode CAT_PD of the optical driving device PD. Here, the voltage difference between the high-potential voltage VDD and the low-potential voltage VSS can be greater than or equal to a threshold voltage at which the optical driving device PD can generate a specific light. For example, if the optical driving device PD is a type of diode, the voltage difference between the high-potential voltage VDD and the low-potential voltage VSS can be greater than or equal to a threshold voltage of the optical driving device PD.

The voltage difference between the anode electrode AND_PD and the cathode electrode CAT_PD of the optical driving device PD can increase, so that the optical driving device PD can emit light. If the optical driving device PD emits light, the optical driving device PD can emit a specific light (e.g., infrared light) of a first wavelength band.

For example, the driving enable control signal PD_EN can correspond to a first emission control signal EM1 that controls an emission timing of at least one first light emitting device ED1 among the plurality of light emitting devices ED. The driving enable control signal PD_EN can be the same as the first emission control signal EM1, or can be different from the first emission control signal EM1.

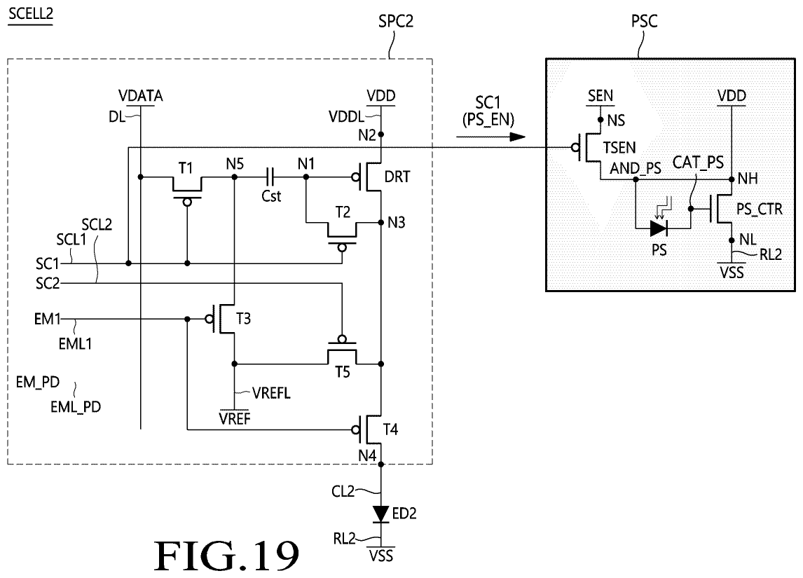

FIG. 19 illustrates a second sub-cell SCELL2 included as an optical sensing sub-cell SCELL_S in an optical sensing area PSA in a display device 100 according to embodiments of the present disclosure.

Referring to FIG. 19, the second sub-cell SCELL2 included as an optical sensing sub-cell SCELL_S in the optical sensing area PSA can include an optical sensing circuit PSC. The second sub-cell SCELL2 can further include a second light emitting device ED2 and a second sub-pixel circuit SPC2 for driving the second light emitting device ED2. The second sub-pixel circuit SPC2 can be the same as the sub-pixel circuit SPC of FIG. 12. Therefore, the description of the second sub-pixel circuit SPC2 will be omitted.

The optical sensing circuit PSC can include an optical detection device PS. The optical detection device PS can include an anode electrode AND_PS and a cathode electrode CAT_PS. The anode electrode AND_PS of the optical detection device PS can be electrically connected to a high-potential voltage node NH to which a high-potential voltage VDD is applied.

The optical detection device PS can conduct forward current from the anode electrode AND_PS to the cathode electrode CAT_PS according to a specific light incident into the interior of the display device 100.

Among the plurality of drivers DRV, the second driver DRV2 arranged in the second sub-cell SCELL2 can be electrically connected to the second row line RL2.

The optical sensing circuit PSC can further include an optical detection control transistor PS_CTR and a sensing transistor TSEN.

The optical detection control transistor PS_CTR can control the connection between the high-potential voltage node NH and the low-potential voltage node NL according to the voltage of the cathode electrode CAT_PS of the optical detection device PS. Here, a high-potential voltage VDD can be applied to the high-potential voltage node NH. The low-potential voltage node NL can be electrically connected to the second row line RL2. The second row line RL2 can be electrically connected to a second electrode of the second light emitting device ED2 included in the second sub-cell SCELL2.

For example, the optical detection control transistor PS_CTR can be an n-type transistor. If the high-potential voltage VDD is applied to the gate node of the optical detection control transistor PS_CTR, the optical detection control transistor PS_CTR can be turned on.

The sensing transistor TSEN can control the connection between the anode electrode AND_PS of the optical detection device PS and a sensing node NS according to the sensing enable control signal EN_SEN.

If the optical driving device PD in the first sub-cell SCELL1 does not emit a specific light or if the specific light is not incident on the optical detection device PS, the forward current does not flow through the optical detection device PS. Accordingly, the optical detection control transistor PS_CTR can have a turn-off state, and the anode electrode AND_PS of the optical detection device PS can maintain a high-potential voltage VDD. In this case, if the sensing transistor TSEN is turned on, the voltage (e.g., sensing voltage) of the sensing node NS can have a high-potential voltage VDD.

If the sensing voltage of the sensing node NS has a high-potential voltage VDD, it can mean that no touch has occurred around the second sub-cell SCELL2.

If the optical driving device PD in the first sub-cell SCELL1 emits a specific light, the specific light can be emitted to the outside of the display device 100 and reflected by a touch pointer (e.g., a finger, a pen, etc.). The specific light reflected by the touch pointer can be incident into the inside of the display device 100, and the incident specific light can reach the optical detection device PS in the second sub-cell SCELL2.

The optical detection device PS can conduct forward current from the anode electrode AND_PS to the cathode electrode CAT_PS by reacting to the specific light incident into the inside of the display device 100. Accordingly, a high-potential voltage VDD is applied to the gate node of the optical detection control transistor PS_CTR, so that the optical detection control transistor PS_CTR can be turned on.

If the optical detection control transistor PS_CTR is turned on, the anode electrode AND_PS of the optical detection device PS can have a low-potential voltage VSS. In this case, if the sensing transistor TSEN is turned on, the voltage (e.g., sensing voltage) of the sensing node NS can have a low-potential voltage VSS.

If the sensing voltage of the sensing node NS has a low-potential voltage VSS, it can mean that a touch has occurred around the second sub-cell SCELL2.

The second sub-cell SCELL2 can include a second row line RL2 different from the first row line RL1, and a second driver DRV2 electrically connected to the second row line RL2.

The optical detection device PS included in the optical sensing circuit PSC can be included in the second sub-cell SCELL2, and can be arranged outside the second driver DRV2.

The optical detection control transistor PS_CTR and the sensing transistor TSEN included in the optical sensing circuit PSC can be included in the second driver DRV2. A second sub-pixel circuit SPC2 can be included in the second driver DRV2.

The second driver DRV2 can include a column driver C-DRV2 that drives a column line CL electrically connected to a first electrode of at least one of two or more second light emitting devices ED2 overlapping with the second row line RL2.

The second sub-pixel circuit SPC2 can include a column driver C-DRV2.

The sensing enable control signal EN_SEN can be the same signal as a first scan signal SC1 used in the column driver C-DRV2 included in the second sub-pixel circuit SPC2.

If the first transistor T1 and the second transistor T2 are turned on by the first scan signal SC1, the data voltage VDATA can be applied to the first node N1. For example, during the data writing period in which the data voltage VDATA is applied to the first node N1 and the storage capacitor Cst is charged, the sensing transistor TSEN can be also turned on, so that the sensing voltage of the sensing node NS can be detected by the second driver DRV2.

Therefore, the sensing transistor TSEN can be a transistor of the same type as the first transistor T1 and the second transistor T2. For example, the sensing transistor TSEN, the first transistor T1, and the second transistor T2 can be p-type transistors. For another example, the sensing transistor TSEN, the first transistor T1, and the second transistor T2 can be n-type transistors.

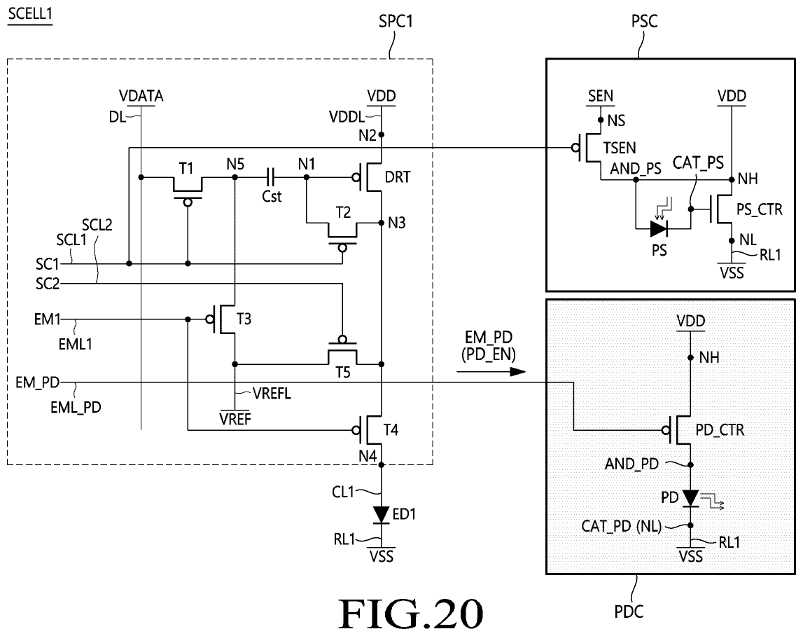

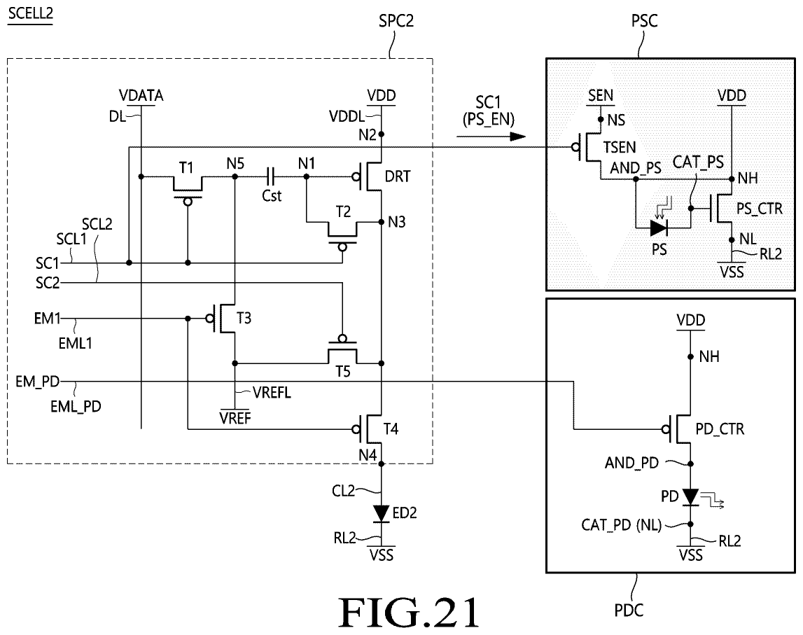

FIG. 20 illustrates a first sub-cell SCELL1 included as an optical driving sub-cell SCELL_D in an optical driving area PDA in a display device 100 according to embodiments of the present disclosure. FIG. 21 illustrates a second sub-cell SCELL2 included as an optical sensing sub-cell SCELL_S in an optical sensing area PSA in a display device 100 according to embodiments of the present disclosure.

The first sub-cell SCELL1 of FIG. 20 is a modified example of the first sub-cell SCELL1 of FIG. 18. Since the first sub-cell SCELL1 is an optical driving sub-cell SCELL_D, the first sub-cell SCELL1 can include an optical driving circuit PDC.

Referring to FIG. 20, though the first sub-cell SCELL1 is an optical driving sub-cell SCELL_D, the first sub-cell SCELL1 can further include an optical sensing circuit PSC. However, the optical sensing circuit PSC included in the first sub-cell SCELL1 can be in a deactivated state and not operating.

The second sub-cell SCELL2 of FIG. 21 is a modified example of the second sub-cell SCELL2 of FIG. 19. Since the second sub-cell SCELL2 is an optical sensing sub-cell SCELL_S, the second sub-cell SCELL2 can include an optical sensing circuit PSC.

Referring to FIG. 21, though the second sub-cell SCELL2 is an optical sensing sub-cell SCEL_S, the second sub-cell SCELL2 can further include an optical driving circuit PDC. However, the optical driving circuit PDC included in the second sub-cell SCELL2 can be in an inactive state that does not operate.

As described above, if the first sub-cell SCELL1, which is an optical driving sub-cell SCELL_D, includes an optical sensing circuit PSC in a deactivated state, and the second sub-cell SCELL2, which is an optical sensing sub-cell SCELL_S, includes an optical driving circuit PDC in a deactivated state, the first driver DRV1 and the second driver DRV2 have an advantage in that they can be designed and manufactured identically. In addition, there is an advantage in that the panel design and panel manufacturing, excluding the first driver DRV1 and the second driver DRV2, can be performed identically.

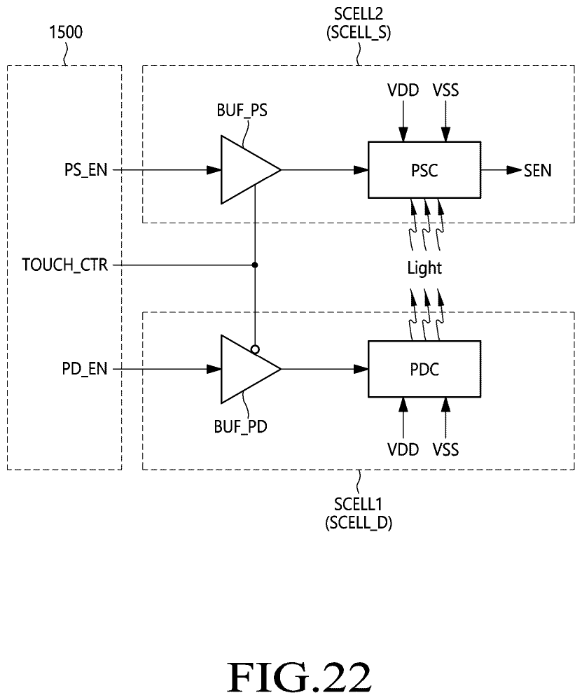

FIG. 22 illustrates an optical touch sensing system of a display device 100 according to embodiments of the present disclosure. FIG. 18 and FIG. 19 are also referred to in the following description.

Referring to FIG. 22, the controller 1500 can control the operation timing of each of the optical driving circuit PDC included in the first sub-cell SCELL1 which is the optical driving sub-cell SCELL_D and the optical sensing circuit PSC included in the second sub-cell SCELL2 which is the optical sensing sub-cell SCELL_S.

The optical driving circuit PDC can be supplied with a high-potential voltage VDD and a low-potential voltage VSS, and can emit a specific light according to a control of the controller 1500.

The optical sensing circuit PSC can be supplied with a high-potential voltage VDD and a low-potential voltage VSS, and can output a sensing voltage SEN through light detection according to a control of the controller 1500.

The controller 1500 can determine the presence or absence of a touch or a touch location based on sensing data generated based on the sensing voltage SEN.

The first sub-cell SCELL1 can include a first buffer BUF_PD and an optical driving circuit PDC. The remaining circuits excluding the optical driving device PD among the optical driving circuit PDC can be included in the first driver DRV1. The first buffer BUF_PD can be included in the first driver DRV1.

The second sub-cell SCELL2 can include a second buffer BUF_PS and an optical sensing circuit PSC. The optical sensing circuit PSC can be included in the second driver DRV2 except for the optical detection device PS. The second buffer BUF_PS can be included in the second driver DRV2.

The controller 1500 can output an optical driving enable signal PD_EN for enabling the operation of the optical driving circuit PDC (e.g., optical driving operation), an optical sensing enable signal PS_EN for enabling the operation of the optical sensing circuit PSC (e.g., optical sensing operation), and a touch control signal TOUCH_CTR.

The touch control signal TOUCH_CTR can have a high level voltage or a low level voltage.

The first buffer BUF_PD can operate by receiving power from a signal that inverts the touch control signal TOUCH_CTR.

The first buffer BUF_PD can receive an optical driving enable signal PD_EN and, can output the optical driving enable signal PD_EN or may not output the optical driving enable signal PD_EN depending on the supplied power state.

The second buffer BUF_PS can operate by receiving the touch control signal TOUCH_CTR as power.

The second buffer BUF_PS can receive an optical sensing enable signal PS_EN and, can output the optical sensing enable signal PS_EN or may not output the optical sensing enable signal PS_EN depending on the supplied power state.

If the touch control signal TOUCH_CTR has a low level voltage, the first buffer BUF_PD can be supplied with the high level voltage of the inverted touch control signal TOUCH_CTR as power and output the optical driving enable signal PD_EN. Accordingly, the optical driving circuit PDC in the first sub-cell SCELL1 can operate.

If the touch control signal TOUCH_CTR has a low level voltage, the second buffer BUF_PS can be supplied with the low level voltage of the touch control signal TOUCH_CTR as power and may not output the optical sensing enable signal PS_EN. Accordingly, the optical sensing circuit PSC in the second sub-cell SCELL2 may not operate.

If the touch control signal TOUCH_CTR has a high level voltage, the first buffer BUF_PD may not output the optical driving enable signal PD_EN by being supplied with the low level voltage of the touch control signal TOUCH_CTR as power. Accordingly, the optical driving circuit PDC in the first sub-cell SCELL1 may not operate.

If the touch control signal TOUCH_CTR has a high level voltage, the second buffer BUF_PS can be supplied with the high level voltage of the touch control signal TOUCH_CTR as power, and output the optical sensing enable signal PS_EN. Accordingly, the optical sensing circuit PSC in the second sub-cell SCELL2 can operate.

For example, the optical driving enable signal PD_EN can correspond to the driving enable control signal PD_EN and the optical driving emission control signal EM_PD. The optical sensing enable signal PS_EN can correspond to the sensing enable control signal EN_SEN and the first scan signal SC1.

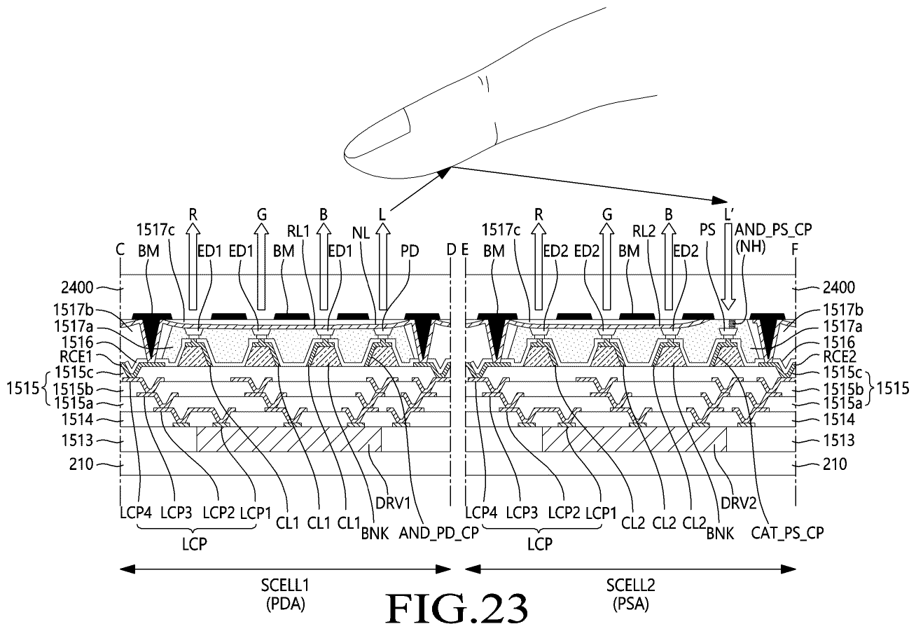

FIG. 23 is a cross-sectional view of an optical driving area PDA and an optical sensing area PSA in a display panel 110 according to embodiments of the present disclosure. FIG. 10 and FIG. 17 to FIG. 19 are also referred to in the following description. In the following description, any description overlapping with FIG. 10 and FIG. 17 to FIG. 19 can be omitted.

FIG. 23 is a cross-sectional view (e.g., cross-sectional view taken along the C-D line of FIG. 17) of a part of a first sub-cell SCELL1 included in an optical driving area PDA, and a cross-sectional view (e.g., cross-sectional view taken along the E-F line of FIG. 17) of a part of a second sub-cell SCELL2 included in an optical sensing area PSA.

Referring to FIG. 23, the display panel 110 can further include a substrate 210, a side protection layer 1513 disposed on each side of the first and second drivers DRV1 and DRV2 disposed on the substrate 210, an upper protection layer 1514 disposed on the side protection layer 1513 and the first and second drivers DRV1 and DRV2, an insulating layer 1515 disposed on the upper protection layer 1514, a bank BNK disposed on the insulating layer 1515 and on which a plurality of light emitting devices ED1 and ED2 are mounted, and a first optical layer 1517a disposed on the side of the plurality of light emitting devices ED1 and ED2.

The side protection layer 1513 can have a height corresponding to a height of the first and second drivers DRV1 and DRV2. For example, the side protection layer 1513 can include at least one organic layer. Accordingly, the side protection layer 1513 can prevent or reduce the first and second drivers DRV1 and DRV2 from falling over.

The insulating layer 1515 can include a plurality of insulating layers. For example, the insulating layer 1515 can include a first insulating layer 1515a, a second insulating layer 1515b, and a third insulating layer 1515c. For example, each of the plurality of insulating layers can be an organic layer.

A plurality of light emitting devices ED1 and ED2, an optical driving device PD, and an optical detection device PS can be mounted on the bank BNK.

The display panel 110 can further include a passivation layer 1516 disposed on the insulating layer 1515.

The display panel 110 according to the embodiments of the present disclosure can further include a second optical layer 1517b surrounding the first optical layer 1517a, and a third optical layer 1517c disposed on the first and second row lines RL1 and RL2.

The display panel 110 according to the embodiments of the present disclosure can further include a black matrix BM disposed on the third optical layer 1517c and having an opening overlapping with a plurality of light emitting devices ED, and an overcoat layer 2400 disposed on the black matrix BM, overlapping with the optical driving device PD and the optical detection device PS, and including a transparent insulating material. The overcoat layer 2400 can be an insulating layer made of a transparent material and having a planarization function.

The plurality of light emitting devices ED1 and ED2 can include a light emitting device that emits a first color light (R), a light emitting device that emits a second color light (G), and a light emitting device that emits a third color light (B). The first color light (R), the second color light (G), and the third color light (B) can be lights in a visible light wavelength band.

The optical driving device PD can emit a specific light (L) in a first wavelength band different from the visible light wavelength band. For example, the first wavelength band can be an infrared wavelength band. The optical detection device PS can detect a specific light (L′) reflected from a touch point such as a finger and incident internally.

The overcoat layer 2400 can be a transparent insulating layer that is disposed on the plurality of light emitting devices ED1 and ED2, the optical driving device PD, and the optical detection device PS, and can be a light transmissive transparent layer.

Each of the two or more first light emitting devices ED1 and the two or more second light emitting devices ED2 can be vertical light-emitting diodes.

Each of a plurality of first column lines CL1 can be electrically connected to a first electrode of each of the two or more first light emitting devices ED1 overlapping with the first row line RL1.

Each of the plurality of first column lines CL1 can be arranged on the insulating layer 1515, and can extend along a side of the bank BNK to an upper surface of the bank BNK to be electrically connected to the first electrode of each of the two or more first light emitting devices ED1.

The first row line RL1 can be arranged on the first optical layer 1517a and the two or more first light emitting devices ED1.

A plurality of second column lines CL2 can be electrically connected to a first electrode of each of two or more second light emitting devices ED2 overlapping with the second row lines RL2.

Each of the plurality of second column lines CL2 can be arranged on the insulating layer 1515, and can extend along a side of the bank BNK to the upper surface of the bank BNK to be electrically connected to the first electrode of each of two or more second light emitting devices ED2.

The second row lines RL2 can be arranged on the first optical layer 1517a and the two or more second light emitting devices ED2.

For example, the optical driving device PD can be a vertical diode.

The optical driving device PD can be mounted on the bank BNK.

The optical driving device PD can be positioned on the side of two or more first light emitting devices ED1 overlapping with the first row line RL1.

The first row line RL1 can be positioned on the optical driving device PD and electrically connected to the cathode electrode CAT_PD of the optical driving device PD. The first row line RL1 and the cathode electrode CAT_PD of the optical driving device PD can correspond to a low-potential voltage node NL.

The display panel 110 according to the embodiments of the present disclosure can further include an anode connection pattern AND_PD_CP electrically connected to the anode electrode AND_PD of the optical driving device PD.

The anode connection pattern AND_PD_CP can extend from an upper surface of the insulating layer 1515 along a side of the bank BNK to an upper surface of the bank BNK, and can be electrically connected to the anode electrode AND_PD of the optical driving device PD.

The anode connection pattern AND_PD_CP can be electrically connected to the anode electrode AND_PD of the optical driving device PD through a hole of the passivation layer 1516 arranged on the side surface and the upper surface of the bank BNK.

For example, the optical detection device PS can be a vertical diode.

The optical detection device PS can be mounted on the bank BNK.

The optical detection device PS can be positioned on the side of two or more second light emitting devices ED2 that overlap with a second row line RL2 different from the first row line RL1 among the plurality of row lines RL.

The display panel 110 can further include an anode connection pattern AND_PS_CP electrically connected to the anode electrode AND_PS of the optical detection device PS, and a cathode connection pattern CAT_PS_CP electrically connected to the cathode electrode CAT_PS of the optical detection device PS.

The cathode connection pattern CAT_PS_CP can extend from the upper surface of the insulating layer 1515 along a side of the bank BNK to the upper surface of the bank BNK, and can be electrically connected to the cathode electrode CAT_PS of the optical detection device PS.

The cathode connection pattern CAT_PS_CP electrically connected to the cathode electrode CAT_PS of the optical detection device PS can be arranged in the same metal layer as the anode connection pattern AND_PD_CP electrically connected to the anode electrode AND_PD of the optical driving device PD.

The anode connection pattern AND_PS_CP electrically connected to the anode electrode AND_PS of the optical detection device PS can be arranged in the same metal layer as the first row line RL1 and the second row line RL2.

The display panel 110 according to the embodiments of the present disclosure can further include a first row connection electrode RCE1 electrically connected to the first row line R1. The first row connection electrode RCE1 can be disposed in the same metal layer as the first column lines CL1.

The display panel 110 according to the embodiments of the present disclosure can further include a line connection pattern LCP electrically connecting the first row connection electrode RCE1 and the first driver DRV1. The line connection pattern LCP can include first to fourth line connection patterns LCP1 to LCP4.

The display panel 110 can further include a second row connection electrode RCE2 electrically connected to the second row line R2. The second row connection electrode RCE2 can be disposed in the same metal layer as the second column lines CL2.

The display panel 110 according to the embodiments of the present disclosure can further include a line connection pattern LCP that electrically connects the second row connection electrode RCE2 and the second driver DRV2. The line connection pattern LCP can include first to fourth line connection patterns LCP1 to LCP4.

The optical driving device PD and the optical detection device PS as an optical touch sensor can have a structure corresponding to the light emitting device ED1 and ED2 for the display. Accordingly, the design and manufacturing of the display panel 110 can be facilitated, and process optimization can also be possible.

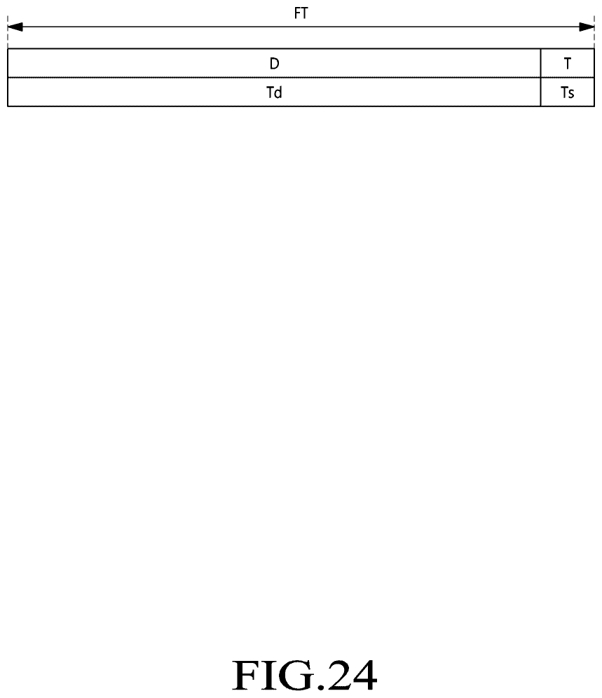

FIGS. 24 to 26 are driving timing diagrams of a display device 100 according to embodiments of the present disclosure.

Referring to FIGS. 24 to 26, one frame period FT of the display device 100 according to the embodiments of the present disclosure can include an optical driving period Td for an optical touch driving in which an optical driving device PD emits a specific light, and an optical sensing period Ts for an optical touch sensing in which an optical detection device PS detects a specific light reflected from the outside of the display device 100 and incident on the inside of the display device 100 and senses a touch.

During the optical driving period Td, at least one of the plurality of light emitting devices ED can emit light. During the touch period (T, T1 to T2, T1 to T4) rather than the display period (D, D1 to D2, D1 to D4), the optical sensing operation can be performed. During the display period (D, D1 to D2, D1 to D4), at least one of the plurality of light emitting devices ED can emit light for image display.

Accordingly, it is possible to reduce noise caused by light emission for image display during optical touch sensing.

Referring to FIG. 24, one frame period FT can include one display period D and one touch period T. During one display period D, the image display can be performed for the entire screen. During one touch period D, touch sensing can be performed for the entire screen.

One display period D can correspond to an optical driving period Td. For example, optical driving can be performed using optical driving devices PD during one display period D.

One touch period T can correspond to an optical sensing period Ts. For example, during one touch period T, optical sensing using optical detection devices PS can be performed.

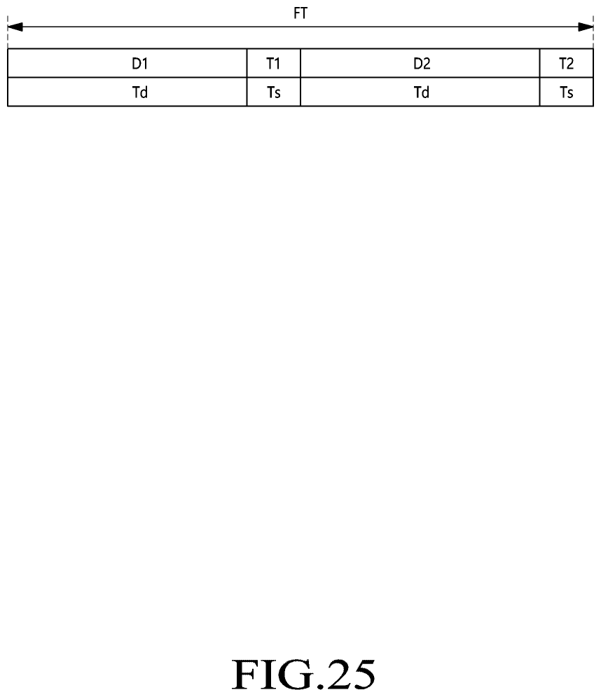

Referring to FIG. 25, one frame period FT can include first and second display periods D1 and D2, and first and second touch periods T1 and T2. The first display period D1, the first touch period T1, the second display period D2, and the second touch period T2 can be performed in sequence.

During the first and second display periods D1 and D2, the image display can be performed on the entire screen. During the first and second touch periods T1 and T2, the touch sensing can be performed on the entire screen.

The first and second display periods D1 and D2 can correspond to the optical driving period Td. For example, during the first and second display periods D1 and D2, optical driving using optical driving devices PD can be performed.

The first and second touch periods T1 and T2 can correspond to the optical sensing period Ts. For example, during the first and second touch periods T1 and T2, optical sensing using optical detection devices PS can be performed.

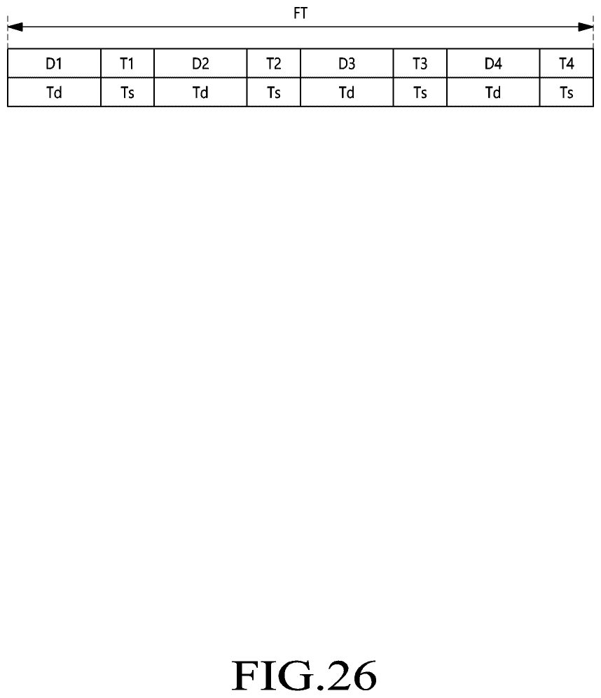

Referring to FIG. 26, one frame period FT can include first to fourth display periods D1 to D4, and first to fourth touch periods T1 to T4. The first display period D1, the first touch period T1, the second display period D2, the second touch period T2, the third display period D3, the third touch period T3, the fourth display period D4, and the fourth touch period T4 can be performed in sequence.

During the first to fourth display periods D1 to D4, the image display can be performed on the entire screen. During the first to fourth touch periods T1 to T4, touch sensing can be performed on the entire screen.

The first to fourth display periods D1 to D4 can correspond to the optical driving period Td. For example, during the first to fourth display periods D1 to D4, optical driving using optical driving devices PD can be performed.

The first to fourth touch periods T1 to T4 can correspond to the optical sensing period Ts. For example, during the first to fourth touch periods T1 to T4, optical sensing using optical detection devices PS can be performed.

The driving timing diagrams of FIGS. 24 to 26 are only examples of the driving timing of the display device 100 according to the embodiments of the present disclosure, and embodiments of the present disclosure are not limited thereto. For example, the driving timing of the display device 100 can be modified in various ways.

Although the embodiments of the present disclosure are described in more detail with reference to the attached drawings, the present disclosure is not necessarily limited to these embodiments, and various modifications can be made without departing from the technical idea of the present disclosure. Accordingly, the embodiments disclosed in the present disclosure are not intended to limit the technical idea of the present disclosure, but to explain, and the scope of the technical idea of the present disclosure is not limited by these embodiments. Therefore, the embodiments described above should be understood as illustrative and not restrictive in all respects.

What is claimed is:

1. A display device comprising:
a substrate;
a plurality of light emitting devices disposed on the substrate and positioned in a display area;
a plurality of column lines electrically connected to a first electrode of each of the plurality of light emitting devices;
a plurality of row lines electrically connected to a second electrode of each of the plurality of light emitting devices;
an optical driving device positioned in the display area on the substrate, the optical driving device overlapping with a first row line among the plurality of row lines, and configured to emit a specific light of a first wavelength band according to a voltage difference between both ends of the optical driving device; and
an optical detection device disposed on the substrate, and configured to detect a specific light reflected from an outside of the display device and incident into the display device.

2. The display device of claim 1, further comprising a plurality of drivers electrically connected to the plurality of column lines and the plurality of row lines,
wherein the display area includes a plurality of cells, and each of the plurality of cells includes a plurality of sub-cells corresponding to the plurality of drivers,
wherein the plurality of cells include a first cell and a second cell, and
wherein at least one of a plurality of first sub-cells included in the first cell includes the optical driving device, and at least one of a plurality of second sub-cells included in the second cell includes the optical detection device.

3. The display device of claim 1, further comprising a plurality of drivers electrically connected to the plurality of column lines and the plurality of row lines,
wherein the display area includes a plurality of cells, and each of the plurality of cells includes a plurality of sub-cells corresponding to the plurality of drivers,
wherein the plurality of sub-cells include a first sub-cell and a second sub-cell, and
wherein the first sub-cell includes the optical driving device, and the second sub-cell includes the optical detection device.

4. The display device of claim 1, further comprising a plurality of drivers electrically connected to the plurality of column lines and the plurality of row lines,
wherein the plurality of drivers include a first driver electrically connected to the first row line, and
wherein the first driver is configured to generate a voltage difference between an anode electrode and a cathode electrode of the optical driving device.

5. The display device of claim 4, wherein the first row line is electrically connected to a second electrode of each of two or more first light emitting devices among the plurality of light emitting devices, and the first row line is electrically connected to the cathode electrode of the optical driving device.

6. The display device of claim 4, further comprising an optical driving control transistor configured to control a connection between a high-potential voltage node and the anode electrode of the optical driving device,
wherein a high-potential voltage is applied to the high-potential voltage node.

7. The display device of claim 6, wherein the optical driving control transistor is included in one of the plurality of drivers.

8. The display device of claim 6, wherein the optical driving control transistor is configured to be turned on or off according to a driving enable control signal, and
wherein the driving enable control signal corresponds to an emission control signal that controls an emission timing of at least one of the plurality of light emitting devices.

9. The display device of claim 1, wherein the optical detection device includes an anode electrode and a cathode electrode, and
wherein the optical detection device is configured to conduct forward current from the anode electrode to the cathode electrode according to a specific light incident into an interior of the display device,
wherein the anode electrode of the optical detection device is electrically connected to a high-potential voltage node to which a high-potential voltage is applied, and
wherein the display device further comprises:
an optical detection control transistor configured to control a connection between the high-potential voltage node and a low-potential voltage node to which a low-potential voltage is applied, according to a voltage of the cathode electrode of the optical detection device; and
a sensing transistor configured to control a connection between the anode electrode of the optical detection device and a sensing node.

10. The display device of claim 9, further comprising a plurality of drivers electrically connected to the plurality of column lines and the plurality of row lines,
wherein the optical detection control transistor and the sensing transistor are included in one of the plurality of drivers.

11. The display device of claim 10, wherein the sensing transistor is configured to be turned on or off according to a sensing enable control signal, and
wherein the sensing enable control signal is identical to a scan signal used in one of the plurality of drivers.

12. The display device of claim 9, wherein the low-potential voltage node is electrically connected to a second row line among the plurality of row lines.

13. The display device of claim 1, further comprising:
a plurality of drivers electrically connected to the plurality of column lines and the plurality of row lines;
a side protection layer disposed on a side of each of the plurality of drivers disposed on the substrate;
an upper protection layer disposed on the side protection layer and the plurality of drivers;
an insulating layer disposed on the upper protection layer;
a bank disposed on the insulating layer, wherein the plurality of light emitting devices, the optical driving devices, and the optical detection devices are disposed on the bank; and
a first optical layer disposed on a side of the plurality of light emitting devices.

14. The display device of claim 13, wherein the optical driving device is a vertical diode mounted on the bank,
wherein the optical driving device is positioned on the side of two or more first light emitting devices overlapping with the first row line,
wherein the first row line is arranged on the optical driving device, the first row line electrically connected to a cathode electrode of the optical driving device, and
wherein the display device further comprises an anode connection pattern extending from an upper surface of the insulating layer along a side of the bank to an upper surface of the bank, the anode connection pattern electrically connected to an anode electrode of the optical driving device.

15. The display device of claim 13, wherein the optical driving device is a vertical diode mounted on the bank,
wherein the optical driving device is positioned on the side of two or more second light emitting devices overlapping with a second row line different from the first row line among the plurality of row lines, and
wherein the display device further comprises:
an anode connection pattern electrically connected to an anode electrode of the optical detection device; and
a cathode connection pattern extending from an upper surface of the insulating layer along a side of the bank to an upper surface of the bank, the cathode connection pattern electrically connected to a cathode electrode of the optical detection device.

16. The display device of claim 13, wherein each of two or more first light emitting devices is a vertical light-emitting diode,
wherein the plurality of column lines include a plurality of first column lines electrically connected to a first electrode of each of two or more first light emitting devices overlapping with the first row line,
wherein each of the plurality of first column lines is arranged on the insulating layer and extends along a side of the bank to an upper surface of the bank, and
wherein the first row line is arranged on the first optical layer and the two or more first light emitting devices.

17. The display device of claim 13, further comprising:
a second optical layer surrounding the first optical layer;
a third optical layer disposed on the plurality of row lines;
a black matrix disposed on the third optical layer, the black matrix having an opening overlapping with the plurality of light emitting devices; and
an overcoat layer disposed on the black matrix, the overcoat layer overlapping with the optical driving device and the optical detection device, and the overcoat layer including a transparent insulating material.

18. The display device of claim 1, wherein the first wavelength band is a wavelength band different from a wavelength band of light emitted from the plurality of light emitting devices.

19. The display device of claim 1, wherein the first wavelength band is an infrared wavelength band.

20. The display device of claim 1, wherein a frame period includes an optical driving period in which the optical driving device emits the specific light of the first wavelength band, and an optical sensing period in which the optical detection device detects the specific light reflected from the outside of the display device and incident into the display device, and
wherein, during the optical driving period, at least one of the plurality of light emitting devices is configured to emit light.

21. A display device comprising:
a plurality of light emitting devices disposed on a substrate and positioned in a display area;
a plurality of drivers configured to drive the plurality of light emitting devices;
an optical driving device disposed on the substrate and positioned in the display area, the optical driving device configured to emit a specific light of a first wavelength band; and
an optical detection device disposed on the substrate and positioned in the display area, the optical detection device configured to detect a specific light reflected from an outside of the display device and incident towards inside of the display device,
wherein the optical driving device is driven by a first driver among the plurality of drivers, and the optical detection device is driven by a second driver among the plurality of drivers.

22. The display device of claim 21, wherein the plurality of drivers are disposed on the substrate and positioned in the display area.

23. The display device of claim 21, wherein the specific light of the first wavelength band has a wavelength band different from a wavelength band of light emitted from the plurality of light emitting devices.

24. The display device of claim 21, wherein the optical driving device is positioned on a side of a first light emitting device among the plurality of light emitting devices, and the optical detection device is positioned on a side of a second light emitting device among the plurality of light emitting devices.

25. The display device of claim 24, further comprising:
a bank disposed on the substrate, wherein the plurality of light emitting devices, the optical driving device, and the optical detection device are mounted on the bank; and
a transparent insulating layer disposed on the plurality of light emitting devices, the optical driving device, and the optical detection device.
